(19) United States
(12) Patent Application Publication
(10) Pub. No.: US 2026/0173719 A1
(43) Pub. Date: Jun. 18, 2026

(54) DISPLAY PANEL

(71) Applicants: Hefei Visionox Technology Co., Ltd., Hefei (CN); Hefei Visionox Electronics Co., Ltd., Hefei (CN); Visionox Technology Inc., Kunshan (CN)

(72) Inventors: Zhiwei ZHOU, Hefei (CN); Yuan YAO, Hefei (CN); Lu ZHANG, Hefei (CN); Zhen FU, Hefei (CN); Guodong LIU, Hefei (CN); Jinfang ZHANG, Hefei (CN); Zhonghou WU, Hefei (CN)

(73) Assignees: Hefei Visionox Technology Co., Ltd., Hefei (CN); Hefei Visionox Electronics Co., Ltd., Hefei (CN); Visionox Technology Inc., Kunshan (CN)

(21) Appl. No.: 19/426,156

(22) Filed: Dec. 19, 2025

Related U.S. Application Data
(63) Continuation of application No. PCT/CN2025/131656, filed on Oct. 31, 2025.

(30) Foreign Application Priority Data
Dec. 13, 2024 (CN) 202411849427.9

(51) Int. Cl. H10K 59/80; H10K 59/122; H10K 59/35; H10K 59/40; H10K 102/00

(52) U.S. Cl. CPC H10K 59/8723; H10K 59/122; H10K 59/352; H10K 59/353; H10K 59/40; H10K 59/80515; H10K 59/80521; H10K 2102/351

(57) ABSTRACT

Disclosed is a display panel. The display panel includes a baseplate, and an isolation structure, a pixel defining layer, and a plurality of light-emitting devices located on the baseplate. The light-emitting device includes a first electrode, a light-emitting functional layer, and a second electrode sequentially stacked on the baseplate. The isolation structure includes isolation openings. The pixel defining layer includes a pixel opening communicated with the isolation opening. The light-emitting functional layer and the second electrode of the light-emitting device are confined in the isolation opening and the pixel opening. At the pixel opening and the isolation opening, orthogonal projections on the baseplate of at least two positions on an edge of the pixel opening are at differing distances from an orthogonal projection on the baseplate of an edge of the isolation opening. By offsetting the pixel opening, impedance between the second electrode and the isolation structure is decreased.

### CROSS-REFERENCE TO RELATED APPLICATIONS

The present application is a continuation of International Application No. PCT/CN 2025/131656, filed on Oct. 31, 2025, which claims priority to Chinese Patent Application No. 202411849427.9, filed on Dec. 13, 2024. The disclosures of the aforementioned applications are hereby incorporated by reference in their entireties.

### FIELD

The present disclosure relates to the field of display technologies, and in particular, to a display panel.

### BACKGROUND

An Organic Light-Emitting Diode (OLED) is an organic thin-film electroluminescent device. Due to advantages such as simple manufacturing process, low cost, low power consumption, high brightness, wide viewing angle, high contrast ratio, and the ability to achieve flexible display, OLED has attracted great attention and is widely used in electronic display products.

However, current electronic display products are limited by structural design, making it difficult to ensure the display performance.

### SUMMARY

A first aspect of the present disclosure provides a display panel. The display panel includes a baseplate, and an isolation structure, a pixel defining layer, and a plurality of light-emitting devices located on the baseplate. The light-emitting device includes a first electrode, a light-emitting functional layer, and a second electrode sequentially stacked on the baseplate. The isolation structure includes a plurality of isolation openings. The pixel defining layer includes a pixel opening communicated with the isolation opening. The light-emitting functional layer and the second electrode of the light-emitting device are confined in the isolation opening and the pixel opening. At the pixel opening and the isolation opening of at least one light-emitting device, orthogonal projections on the baseplate of at least two positions on an edge of the pixel opening are at differing distances from an orthogonal projection on the baseplate of an edge of the isolation opening.

In the above-mentioned solution, by offsetting the pixel opening, the light-emitting device may be offset towards a side, and the side allows the second electrode and the isolation structure to form an overlap more easily (with high overlap quality), thereby further reducing the difficulty of the overlap between the second electrode and the isolation structure on the side. Thus, without increasing a thickness of the second electrode, impedance between the second electrode and the isolation structure may be reduced.

A second aspect of the present disclosure provides a display panel. The display panel includes a baseplate, and an isolation structure, a pixel defining layer, and a plurality of light-emitting devices located on the baseplate. The light-emitting device includes a first electrode, a light-emitting functional layer, and a second electrode sequentially stacked on the baseplate. The isolation structure includes a plurality of isolation openings. The pixel defining layer includes a pixel opening communicated with the isolation opening. The light-emitting functional layer and the second electrode of the light-emitting device are confined in the isolation opening and the pixel opening. For the pixel opening and the isolation opening of the same light-emitting device, a centroid of an orthogonal projection on the baseplate of the pixel opening is located outside a centroid of an orthogonal projection on the baseplate of the isolation opening.

In the above-mentioned solution, by offsetting the pixel opening, the light-emitting device may be offset towards a side, and the side allows the second electrode and the isolation structure to form an overlap more easily (with high overlap quality), thereby further reducing the difficulty of the overlap between the second electrode and the isolation structure on the side. Thus, without increasing a thickness of the second electrode, impedance between the second electrode and the isolation structure may be reduced.

A third aspect of the present disclosure provides a display panel. The display panel includes a baseplate, and an isolation structure, a pixel defining layer, and a plurality of light-emitting devices located on the baseplate. The light-emitting device includes a first electrode, a light-emitting functional layer, and a second electrode sequentially stacked on the baseplate. The isolation structure includes a plurality of isolation openings. The light-emitting functional layer and the second electrode of the light-emitting device are confined in the isolation opening. At at least one isolation opening, a centroid of an orthogonal projection on the baseplate of the first electrode, is located outside a centroid of an orthogonal projection on the baseplate of the isolation opening.

In the above-mentioned solution, the first electrode may be offset together with the pixel opening (a direction and a magnitude of offset may be the same or different), so as to adjust a distribution of a part of the pixel defining layer covering an edge of the first electrode (the part is lifted by the first electrode), thereby regulating impedance at connections between the second electrode and different positions of the isolation structure.

### BRIEF DESCRIPTION OF THE DRAWINGS

FIG. 1 is a schematic diagram of a planar structure of a display panel provided by an embodiment of the present disclosure.

FIG. 2 is an enlarged view of region S1 of the display panel shown in FIG. 1 under one design.

FIG. 3A is a cross-sectional view of the display panel shown in FIG. 2 taken along M1-N1 under one design.

FIG. 3B is an enlarged view of a sub-pixel of the display panel shown in FIG. 2 under one design.

FIG. 3C is an enlarged view of a sub-pixel of the display panel shown in FIG. 2 under another design.

FIG. 3D is a schematic diagram of a planar structure of a sub-pixel of a display panel in an embodiment of the present disclosure under another design.

FIG. 4A is an enlarged view of region S1 of the display panel shown in FIG. 1 under another design.

FIG. 4B is an enlarged view of a sub-pixel of the display panel shown in FIG. 4A.

FIG. 4C is an enlarged view of another sub-pixel of the display panel shown in FIG. 4A.

FIG. 5 is a cross-sectional view of a partial region of a display panel provided by an embodiment of the present disclosure under another design.

FIG. 6 is an enlarged view of region S1 of the display panel shown in FIG. 1 under another design.

FIG. 7 is an enlarged view of region S1 of the display panel shown in FIG. 1 under another design.

FIG. 8 is a schematic diagram of a planar structure of a sub-pixel of a display panel in an embodiment of the present disclosure under another design.

FIG. 9 is a cross-sectional view of a partial region of a display panel provided by an embodiment of the present disclosure under another design.

FIG. 10 is a cross-sectional view of a partial region of a display panel provided by an embodiment of the present disclosure under another design.

FIG. 11 is a cross-sectional view of a partial region of a display panel provided by an embodiment of the present disclosure under another design.

FIG. 12 is a cross-sectional view of a partial region of a display panel provided by an embodiment of the present disclosure under another design.

FIG. 13 is a cross-sectional view of a partial region of a display panel provided by an embodiment of the present disclosure under another design.

FIG. 14 is an enlarged view of region S1 of the display panel shown in FIG. 1 under another design.

FIG. 15 is a cross-sectional view of a partial region of a display panel provided by an embodiment of the present disclosure under another design.

FIG. 16 is an enlarged view of region S1 of the display panel shown in FIG. 1 under another design.

FIG. 17 is an enlarged view of region S1 of the display panel shown in FIG. 1 under another design.

FIG. 18 is an enlarged view of region S1 of the display panel shown in FIG. 1 under another design.

FIG. 19 is an enlarged view of region S1 of the display panel shown in FIG. 1 under another design.

FIG. 20 is an enlarged view of region S1 of the display panel shown in FIG. 1 under another design.

### DETAILED DESCRIPTION OF THE EMBODIMENTS

The embodiments of the specification may be described clearly and completely with reference to the accompanying drawings. Apparently, the described embodiments are a part rather than all of the embodiments of the present disclosure.

In a display product, several functional layers of a light-emitting device are formed by evaporation. Each light-emitting device includes a plurality of types of functional layers, and materials of some functional layers (for example, a light-emitting layer) differ between the light-emitting devices emitting different colors. Consequently, when the functional layers are evaporated through a mask plate (for example, a fine metal mask), a plurality of alignment steps are required. To address a problem of a position offset caused by a positional accuracy error, sufficient space (a safety margin related to a positional error) is required to be reserved between different light-emitting devices, so as to ensure that an actual light-emitting region of the light-emitting device may overlap with a designed position (a design region). A design area of the light-emitting region of the light-emitting device is effectively reduced. Not only a light-emitting area of the light-emitting device is limited, but also a density of the light-emitting device is prevented from being further increased, so that further improving a Pixels Per Inch (PPI) of the display panel is difficult.

In the present disclosure, an isolation structure is provided, so as to isolate functional layers of adjacent light-emitting devices. Thus, in an evaporation process of the functional layer, an entire surface evaporation can be performed on the display panel, instead of using a mask plate to separately prepare the functional layer for each light-emitting device. The process eliminates the need to consider alignment accuracy during evaporation, thus enabling the design of gaps between the light-emitting devices to be of a less size, thereby increasing PPI.

During a manufacturing process of the light-emitting device, a cathode (for example, a second electrode mentioned below) needs to overlap with the isolation structure, and an edge of the cathode is blocked by the isolation structure. Therefore, during the evaporation process, when the edge of the cathode is ensured to have sufficient thickness to reduce impedance between the cathode and the isolation structure, then a thickness of a layer to be evaporated in each evaporation process may be relatively large, thereby causing a thickness of a middle region of the cathode to increase as well, and seriously reducing a light transmittance of the cathode. On the contrary, when the thickness of the middle region of the cathode is reduced, thereby results in insufficient thickness in an edge part of the cathode, thereby increasing the impedance between the cathode and the isolation structure, and even causing poor overlap between the cathode and the isolation structure.

Furthermore, during a process of preparing the light-emitting device based on the isolation structure, the light-emitting devices are manufactured in batches. Therefore, in the entire process, a plurality of layout processes (including etching) may be used. When the thickness of the edge part of the cathode is small, then during an etching process, the edge part of the cathode is prone to being damaged or even being etched through by the etching, not only leading to poor overlap between the cathode and the isolation structure, but also damaging an underlying film layer (for example, a pixel defining layer mentioned below).

At least one embodiment of the present disclosure provides a display panel to at least address the above-mentioned problem. The display panel includes a baseplate and an isolation structure, and a plurality of light-emitting devices located on the baseplate. The light-emitting device includes a light-emitting region. The isolation structure defines a plurality of isolation openings. The isolation opening confines the light-emitting device. A centroid of an orthogonal projection on the baseplate of the light-emitting region of at least one light-emitting device, is located outside a centroid of an orthogonal projection on the baseplate of a corresponding isolation opening. The centroid mentioned in the present disclosure refers to a center of a geometric figure. In some embodiments, a light-transmitting opening is further provided on the isolation structure. A certain distance may be reserved between the light-emitting device and the light-transmitting opening to prevent a partial structure of the light-emitting device (for example, a first electrode mentioned below) from blocking the light-transmitting opening in an actual production of the display panel. In the display panel, by offsetting the pixel opening, the light-emitting device may be offset towards a side, and the side allows the second electrode and the isolation structure to form a high-quality overlap more easily (with high overlap quality), thereby further reducing difficulty of overlap between the second electrode and the isolation structure on this side. Thus, without increasing a thickness of the second electrode, impedance between the second electrode and the isolation structure may be reduced.

Hereinafter, a structure of the display panel according to at least one embodiment of the present disclosure is described in detail with reference to the accompanying drawings. Furthermore, in the accompanying drawings, a three-dimensional Cartesian coordinate system is established based on the baseplate of the display panel to visually represent positional relationships of various components of the display panel. In the Cartesian coordinate system, a X-axis and a Y-axis are parallel to a plane of the baseplate, while a Z-axis is perpendicular to the plane of the baseplate.

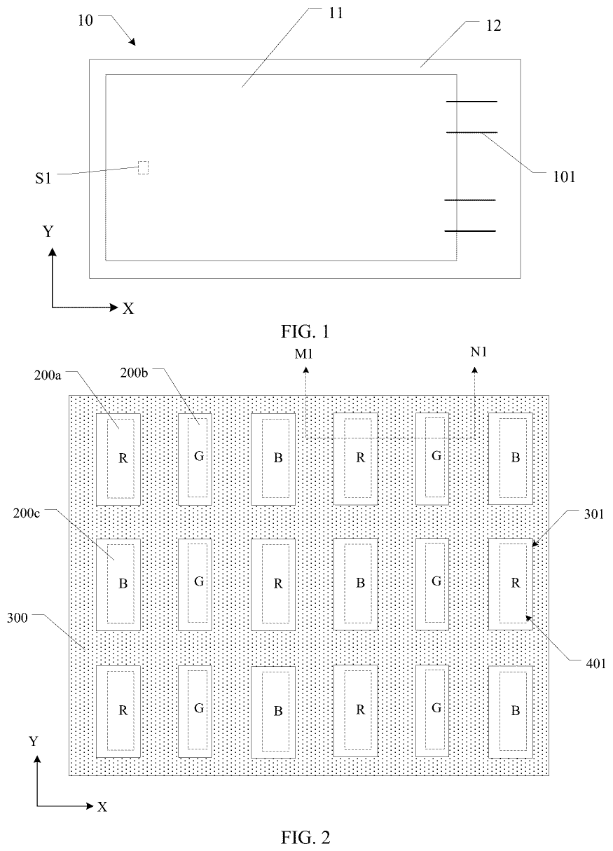

As shown in FIGS. 1, 2, 3A and 3B, a display panel 10 includes a display region 11 and a non-display region 12 surrounding the display region 11. Sub-pixels emitting light of different colors are arranged in the display area 11, such as a red sub-pixel R, a green sub-pixel G, and a blue sub-pixel B. It should be noted that, in some embodiments of the present disclosure, part of wiring in the non-display area 12 may extend into the display area 11, thereby enabling the non-display area 12 to be designed with a single-sided border.

For example, a physical structure of the display panel 10 includes a baseplate 100, and an isolation structure 300, a pixel defining layer 400, and a plurality of light-emitting devices 200 located on the baseplate 100. The light-emitting devices 200 are physical light-emitting structures of sub-pixels, such as the sub-pixel R, the green sub-pixel G, and the blue sub-pixel B.

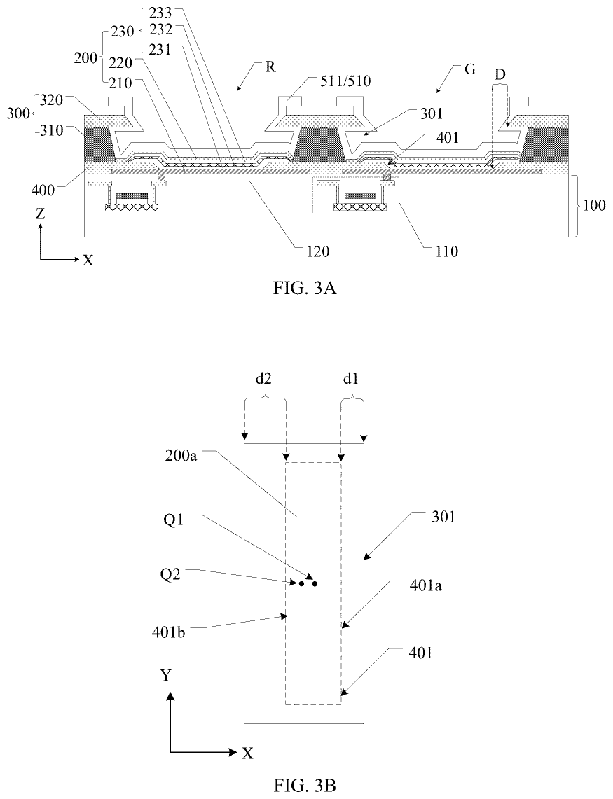

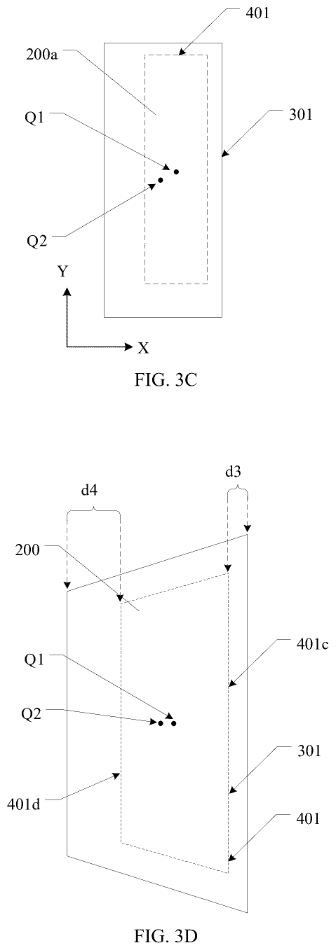

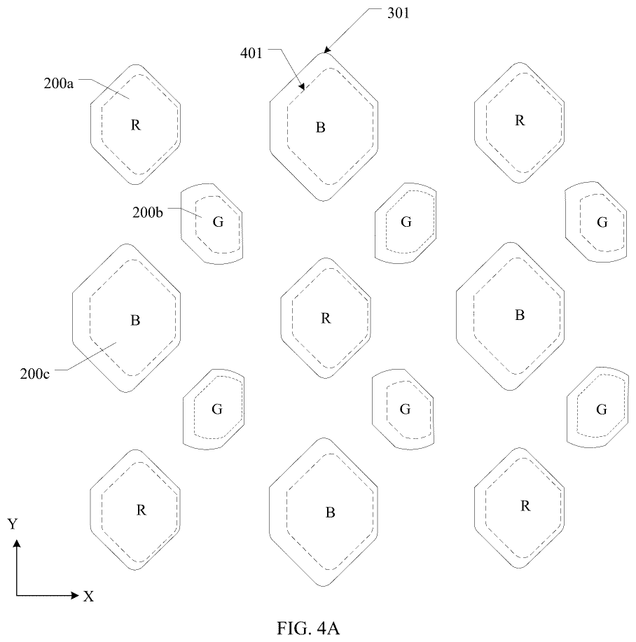

The light-emitting device 200 includes a first electrode 210, a light-emitting functional layer 230, and a second electrode 220 sequentially stacked on the baseplate 100. The isolation structure 300 includes a plurality of isolation openings 301. The pixel defining layer 400 includes a pixel opening 401 communicated with the isolation opening 301. The light-emitting functional layer 230 and the second electrode 220 of the light-emitting device 200 are confined in the isolation opening 301 and the pixel opening 401. At the pixel opening 401 and the isolation opening 301 of at least one light-emitting device 200, orthogonal projections on the baseplate 100 of at least two positions on an edge of the pixel opening 401 is at differing distances from an orthogonal projection on the baseplate 100 of an edge of the isolation opening 301. That is, a centroid of the pixel opening 401 is offset from a centroid of the isolation opening 301. Centroid offset refers to that the centroid of pixel opening 401 on baseplate 100 is located outside the centroid of isolation opening 301 on baseplate 100. That is, the centroid of pixel opening 401 on baseplate 100 is non-coincident with the centroid of isolation opening 301 on baseplate 100. Specifically, as shown in FIG. 3C, a centroid Q1 of the pixel opening 401 is offset from a centroid Q2 of the isolation opening 301. Thus, by offsetting the pixel opening 401, the light-emitting device 200 may be offset towards a side, and the second electrode 220 and the isolation structure 300 may more easily overlap at the side. So that difficulty of overlap between the second electrode 220 and the isolation structure 300 on the side is further reduced, and impedance between the second electrode 220 and the isolation structure 300 may be reduced. Furthermore, on an offset side (the pixel opening 401 is closer to the isolation structure 300 on the side), a thickness of an edge part of the second electrode 220 is relatively greater. Thus, in a manufacturing process of the light-emitting device 200 (manufacturing light-emitting devices 200 in a subsequent batch), anti-etching capability is sufficient. Not only overlap between the second electrode and the isolation structure is ensured, but also an underlying pixel defining layer 400 is protected. In the present disclosure, a distance, between an orthogonal projection of a position on the baseplate and an orthogonal projection of an edge on the baseplate, refers to a minimum distance between the orthogonal projection of the position on the baseplate and the orthogonal projection of the edge on the baseplate. For example, a distance, between an orthogonal projection on the baseplate of a position on an edge of the pixel opening and an orthogonal projection on the baseplate of an edge of the isolation opening, refers to a minimum distance between the orthogonal projection on the baseplate of the position on the edge of the pixel opening and the orthogonal projection on the baseplate of the edge of the isolation opening.

In at least one embodiment of the present disclosure, as shown in FIGS. 2, 3A, and FIG. 3B, at the pixel opening 401 and the isolation opening 301 of at least one light-emitting device 200, the orthogonal projection on the baseplate 100 of the edge of the isolation opening 301 includes a plurality of isolation opening projection edges. A distance, between a centroid Q1 of the orthogonal projection on the baseplate 100 of the pixel opening 401 and a part of the plurality of isolation opening projection edges (for example, a right side edge of the isolation opening 301 as shown in FIG. 3C), is less than a distance between the centroid Q1 of the orthogonal projection on the baseplate 100 of the pixel opening 401 and other part of the plurality of isolation opening projection edges (for example, a left side edge of the isolation opening 301 as shown in FIG. 3C). Thus, by offsetting the pixel opening 401, the light-emitting device 200 is closer to a side of the isolation structure 300, thereby enabling the second electrode 220 of the light-emitting device 200 to have a better connection with the isolation structure 300 on the side. For example, on the side, the pixel opening 401 is closer to the isolation structure 300. Therefore, a thickness of a part of the second electrode 220 connected to the isolation structure 300 is greater, and impedance between the second electrode 220 and the isolation structure 300 is further reduced.

For example, in one instance, as shown in FIG. 3B, the number of the isolation opening projection edge with a minimum distance to the centroid Q1 of the orthogonal projection on the baseplate 100 of pixel opening 401 is one. That is, the pixel opening 401 is offset towards one edge of the isolation opening 301 (for example, towards a right direction as shown in FIG. 3B).

For example, in another instance, as shown in FIG. 3C, the number of the isolation opening projection edges with a minimum distance to the centroid Q1 of the orthogonal projection on the baseplate 100 of pixel opening 401 is at least two. That is, the pixel opening 401 is offset towards at least two edges of the isolation opening 301 (for example, towards an upper right direction as shown in FIG. 3B). For example, further, the at least two isolation opening projection edges with a minimum distance to the centroid Q1 of the orthogonal projection on baseplate 100 of pixel opening 401 are connected. That is, the pixel opening 401 is offset towards at least one corner of the isolation opening 301 (for example, an upper right corner of the isolation opening 301 in FIG. 3B).

In at least one embodiment of the present disclosure, as shown in FIG. 3B, an orthogonal projection on the baseplate 100 of the pixel opening 401 includes a first pixel opening projection edge 401a and a second pixel opening projection edge 401b opposite to each other. The orthogonal projection on the baseplate 100 of the pixel opening 401 refers to an orthogonal projection on the baseplate 100 of a region enclosed by a side, closer to the first electrode 210, of a side wall of the pixel opening 401. A distance d1, between the first pixel opening projection edge 401a and the orthogonal projection on the baseplate 100 of the edge of the isolation opening 301, is less than a distance d2 between the second pixel opening projection edge 401b and the orthogonal projection on the baseplate 100 of the edge of the isolation opening 301. Thus, on a side on which the first pixel opening projection edge 401a is located, a width of a part of the second electrode 220 extending onto the pixel defining layer 400 is less. Therefore, during a formation process of the second electrode 220 (for example, an evaporation process), a thickness of the second electrode 220 deposited on the pixel defining layer 400 on the side can be greater, and the second electrode 220 can more easily climb onto a side wall of the isolation structure 300. That is, a thickness and area of a part of the second electrode 220 contacted with the isolation structure 300 are greater, thereby reducing impedance between the second electrode 220 and the isolation structure 300 on the side on which the first pixel opening projection edge 401a is located. In some embodiments, the orthogonal projection on the baseplate 100 of the edge of isolation opening 301 includes straight edges. The first pixel opening projection edge 401a and the orthogonal projection on the baseplate 100 of the edge of the isolation opening 301 are both straight edges and parallel to each other. The second pixel opening projection edge 401b and the orthogonal projection on the baseplate 100 of the edge of the isolation opening 301 are both straight edges and parallel to each other. The first pixel opening projection edge 401a and the second pixel opening projection edge 401b are parallel.

In at least one embodiment of the present disclosure, as shown in FIG. 3D, the orthogonal projection on the baseplate 100 of the pixel opening 401 includes a third pixel opening projection edge 401c and a fourth pixel opening projection edge 401d. A length of the third pixel opening projection edge 401c is greater than a length of the fourth pixel opening projection edge 401d. A distance d3, between the third pixel opening projection edge 401c and the orthogonal projection on the baseplate 100 of the edge of the isolation opening 301, is less than a distance d4 between the fourth pixel opening projection edge 401d and the orthogonal projection on the baseplate 100 of the edge of the isolation opening 301. Thus, on a side with a greater length of pixel opening 401 (the fourth pixel opening projection edge 401d), a contact area (and a length of a contact boundary) between the second electrode 220 and the isolation structure 300 is greater. The pixel opening 401 is offset towards the side with a greater length (the fourth pixel opening projection edge 401d), the impedance between the second electrode 220 and the isolation structure 300 may be further reduced.

In at least one embodiment of the present disclosure, as shown in FIGS. 3A and 3B, the first pixel opening projection edge 401a corresponds to a first side of the isolation opening (for example, a right side in the figures). The second pixel opening projection edge 401b corresponds to a second side of the isolation opening 301 (for example, a left side in the figures). The embodiment further includes at least one of the following embodiments. In some embodiments, the second electrode 220 overlaps with the isolation structure 300. And a distance, between the baseplate 100 and an end, facing away from the baseplate 100, of a part of the second electrode 220 overlapping with the isolation structure 300 on the first side, is greater than a distance between the baseplate 100 and an end, facing away from the baseplate 100, of a part of the second electrode 220 overlapping with the isolation structure 300 on the second side. That is, compared to the second side, on the first side, the edge of the second electrode 220 climbs higher on a side wall of the isolation structure 300. In the some embodiments, the second electrode 220 overlaps with the isolation structure 300. And a thickness, of the part of the second electrode 220 overlapping with the isolation structure 300 on the first side, is greater than a thickness of the part of the second electrode 220 overlapping with the isolation structure 300 on the second side.

During a process of evaporating the second electrode 220 based on the isolation structure 300, due to shielding effect of the isolation structure 300, the closer to the isolation structure 300, the less the evaporated material is deposited. Therefore, the thickness at the edge of the second electrode 220 becomes increasingly less. Assuming a case where no offset is provided, an edge part of the second electrode 220 begins to be contacted with the isolation structure 300 at a first preset thickness. In a case where the pixel opening 401 is offset, on a side on which the first pixel opening projection edge 401a is located, a distance between the edge of the pixel opening 401 and the edge of the isolation opening 301 is reduced. Therefore, the edge part of the second electrode 220 begins to be contacted with the isolation structure 300 when the thickness is greater than the first preset thickness, so that a thickness of a part, located between the pixel opening 401 and the isolation structure 300, of the second electrode 220 (such as an average thickness of the film layer) increases, and a climbing height of the second electrode 220 on the isolation structure 300 also increases (a contact area increases, and a thickness of a contact part also increases), thereby reducing the impedance between the second electrode 220 and the isolation structure 300.

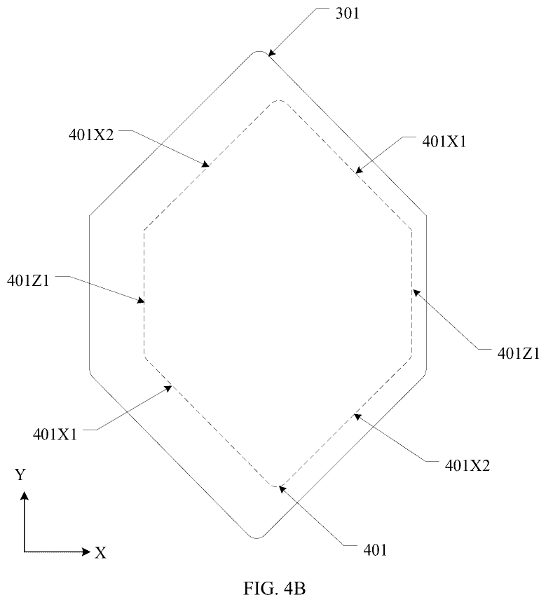

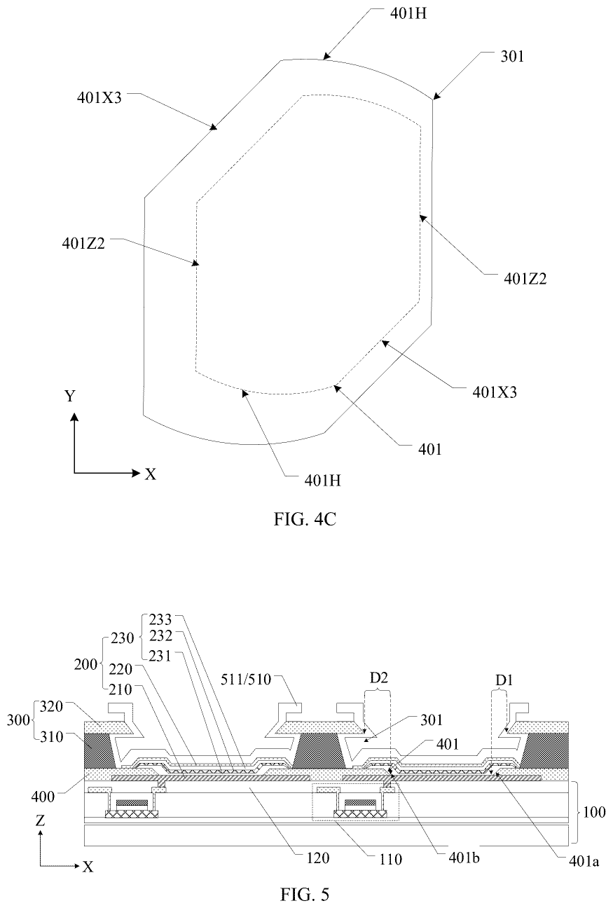

In at least one embodiment of the present disclosure, as shown in FIGS. 4A to 4C, the plurality of light-emitting devices include first-type light-emitting devices 200a, second-type light-emitting devices 200b, and third-type light-emitting devices 200c with different emitting colors. The first-type light-emitting device 200a, the second-type light-emitting device 200b, and the third-type light-emitting device 200c are arranged in a plurality of rows and a plurality of columns. The first-type light-emitting devices 200a and the third-type light-emitting devices 200c are arranged in the same row and the same column. The first-type light-emitting devices 200a and the third-type light-emitting devices 200c alternate in arrangement within the same column and also alternate within the same row. Columns in which the first-type light-emitting device 200a and the third-type light-emitting device 200c are located, alternate with columns in which the second-type light-emitting device 200b is located. Rows in which the first-type light-emitting device 200a and the third-type light-emitting device 200c are located, alternate with rows in which the second-type light-emitting device 200b is located. Under this pixel arrangement, the pixel opening 401 corresponding to the light-emitting device 200 can be offset conveniently, and while a high pixel arrangement density PPI is ensured, the impedance between the second electrode 220 and the isolation structure 300 in the entire display panel is further reduced.

For example, as shown in FIG. 4B, a shape of the at least one pixel opening 401 corresponding to the light-emitting device 200 is a hexagon, and includes two opposite first straight edges 401Z1, two opposite first oblique edges 401X1, and two opposite second oblique edges 401X2. The first straight edge 401Z1 is located between the first oblique edge 401X1 and the second oblique edge 401X2. A distance, between an orthogonal projection on the baseplate 100 of one first straight edge 401Z1 (for example, a right side of the pixel opening 401 in FIG. 4B) and the orthogonal projection on the baseplate 100 of the edge of the isolation opening 301, is less than a distance between an orthogonal projection on the baseplate 100 of the other first straight edge 401Z1 (for example, a left side of the pixel opening 401 in FIG. 4B) and the orthogonal projection on the baseplate 100 of the edge of the isolation opening 301. For example, the first straight edge 401Z1 is parallel to a direction of the column, the first oblique edge 401X1 and the second oblique edge 401X2 intersect the direction of the column and the direction of the row without being perpendicular thereto, and in the pixel openings 401 corresponding to the first-type light-emitting device 200a and the third-type light-emitting device 200c, an area of the first-type light-emitting device 200a is less than an area of the third-type light-emitting device 200c.

For example, as shown in FIG. 4B, in a case where the plurality of light-emitting devices 200 includes first-type light-emitting devices 200a, second-type light-emitting devices 200b and third-type light-emitting devices 200c with different emitting colors, the pixel openings 401 with orthogonal projections on the baseplate 100 of hexagonal shape are the pixel openings 401 corresponding to the first-type light-emitting devices 200a and the third-type light-emitting devices 200c.

As shown in FIG. 4C, the pixel opening 401 corresponding to the second-type light-emitting device 200b includes two opposite second straight edges 401Z2, two opposite third oblique edges 401X 3 and two opposite arc edges 401H. The second straight edge 401Z 2 is located between the third oblique edge 401X 3 and the arc edge 401H. In the pixel opening 401 corresponding to the second-type light-emitting device 200b, a distance, between an orthogonal projection on the baseplate 100 of one second straight edge 401Z2 (for example, a right side of the pixel opening 401 in FIG. 4C) and the orthogonal projection on the baseplate 100 of the edge of the isolation opening 301, is less than a distance between an orthogonal projection on the baseplate 100 of the other second straight edge 401Z2 (for example, a left side of the pixel opening 401 in FIG. 4C) and the orthogonal projection on the baseplate 100 of the edge of the isolation opening 301. The first straight edge 401Z1 and the second straight edge 401Z2 may be parallel or perpendicular to a scan signal line. For example, the second straight edge 401Z2 is parallel to the direction of the column, and the third oblique edge 401X3 intersects the direction of the column and the direction of the row without being perpendicular thereto.

In the embodiments as shown in FIGS. 4A to 4C, the arrangement and shape of the first-type light-emitting device 200a, the second-type light-emitting device 200b and the third-type light-emitting device 200c may facilitate offsetting the pixel opening 401 corresponding to each light-emitting device 200 towards the same side or the opposite side, thereby simplifying a manufacturing process of the display panel and facilitating control of a manufacturing cost of the display panel.

In at least one embodiment of the present disclosure, as shown in FIGS. 4A to 4C, the first straight edge 401Z1 and the second straight edge 401Z2 are parallel, for example, both parallel to the Y-axis direction, thus simplifying the manufacturing process of the display panel and facilitating the control of the manufacturing cost of the display panel.

In the embodiments of the present disclosure, in a case where the pixel opening is offset relative to the isolation opening, an offset distance may be selectively controlled, so that the second electrode still overlaps the isolation structure on two sides in an offset direction (on a closer side, overlapping degree is higher, and the impedance is lower) . In one embodiment, the offset distance may be increased, so that the second electrode overlaps with the isolation structure on one side in the offset direction, thereby achieving a better overlap quality between the second electrode and the isolation structure on an overlapped side, and further reducing the impedance between the second electrode and the isolation structure. The two cases are described separately below with reference to different accompanying drawings.

For example, in one instance, referring to FIGS. 3A and 3B again. On two sides on which the first pixel opening projection edge 401a and the second pixel opening projection edge 401b are located, the second electrode 220 overlaps with the isolation structure 300.

For example, in another instance, as shown in FIG. 5, the first pixel opening projection edge 401a corresponds to a first side of the isolation opening 301, and the second pixel opening projection edge 401b corresponds to a second side of the isolation opening 301. The second electrode 220 overlaps the isolation structure 300 on the first side, and a gap is provided between the second electrode 220 and the isolation structure 300.

During the manufacturing process of the light-emitting device 200, when it is ensured that the second electrode 220 and the isolation structure 300 have a good overlap on two sides on which the first pixel opening projection edge 401a and the second pixel opening projection edge 401b are located, two evaporation processes (corresponding to two different evaporation angles) are required to form the second electrode 220. Thus, when the edge of the second electrode 220 has sufficient thickness on the two sides to reduce the impedance between the second electrode 220 and the isolation structure 300, then the second electrode 220 (for example, a middle region configured for light transmission) may have a relatively large overall thickness, thereby reducing the light transmittance and decreasing a light-emitting rate of the display panel. Or, when the entire second electrode 220 (for example, the middle region configured for light transmission) has a relatively small thickness to ensure light transmittance, then the thickness of the edge of the second electrode 220 on two sides (for example, a first thickness) is limited, making it difficult to reduce the impedance between the second electrode 220 and the isolation structure 300 and even causing contact problems. In the solution as shown in FIG. 5, the second electrode 220 is not required to overlap with the isolation structure 300 on the second side. Therefore, during an evaporation process of the second electrode 220, only one evaporation process is required. Thus, while the thickness of the middle region of the second electrode 220 is ensured to be relatively small to achieve a higher light transmittance at the same time, the edge of the second electrode 220 on the first side has sufficient thickness (a second thickness, for example, twice the first thickness) to reduce the impedance between the second electrode 220 and the isolation structure 300.

In embodiments of the present disclosure, a horizontal spacing between the edge of the pixel opening 401 and the edge of the isolation opening 301 may be set according to a specific requirement, and the horizontal spacing is not limited in the embodiments of the present disclosure.

For example, in at least one embodiment of the present disclosure, referring to FIG. 3A again, a distance D, between the orthogonal projection on the baseplate 100 of the edge of the pixel opening 401 and the orthogonal projection on the baseplate 100 of the edge of the isolation opening 301, ranges from 0.3 μm to 10 μm. For example, the distance D may be 0.3 μm, 0.5 μm, 1 μm, 3 μm, 5 μm, 7 μm, 9 μm, 9.5 μm, 10 μm, and the like.

For example, in at least one embodiment of the present disclosure, as shown in FIG. 5, on the first side (a side on which the first pixel opening projection edge 401a is located), a distance D1, between the orthogonal projection on the baseplate 100 of the edge of the pixel opening 401 and the orthogonal projection on the baseplate 100 of the edge of the isolation opening 301, may range from 0.3 μm to 6 μm. For example, the distance D1 may be 0.3 μm, 0.5 μm, 1 μm, 3 μm, 5 μm, 5.5 μm, and the like.

For example, in at least one embodiment of the present disclosure, as shown in FIG. 5, at the second side (a side on which the second pixel opening projection edge 401b is located), a distance D2, between the orthogonal projection on the baseplate 100 of the edge of the pixel opening 401 and the orthogonal projection on the baseplate 100 of the edge of the isolation opening 301, may be from 0.6 μm to 10 μm. For example, the distance D2 may be 0.6 μm, 0.8 μm, 1.5 μm, 5.5 μm, 3.5 μm, 7.5 μm, 9.5 μm, 10 μm, and the like.

In at least one embodiment of the present disclosure, referring to FIGS. 3A and 3B again, the first pixel opening projection edge 401a corresponds to a first side of the isolation opening 301, an orthogonal projection on the baseplate 100 of the first side of the isolation opening 301 is a straight edge. Thus, the pixel opening 401 is offset towards a side on which the straight edge of the isolation opening 301 is located, thereby further increasing a connection area between the second electrode 220 and the isolation structure 300, and further reducing the impedance between the second electrode 220 and the isolation structure 300.

In at least one embodiment of the present disclosure, referring to FIGS. 1, 2, 3A, and 3B again, the baseplate 100 further includes a scan signal line, the orthogonal projection on the baseplate 100 of the first side of the isolation opening 301 is parallel or perpendicular to the scan signal line (the perpendicular case is shown in FIG. 1). Thus, when the second electrode 220 is formed during an evaporation process, a scanning direction of a nozzle of an evaporation source is perpendicular to the straight edge (an edge of the first side) of the isolation opening, thereby achieving a better overlap effect between the second electrode 220 and the isolation structure 300. Furthermore, when the scan signal line is arranged in the display panel, an extension direction of the scan signal line is perpendicular or parallel to the scanning direction of the nozzle.

In the embodiments of the present disclosure, all the pixel openings may be selected to be offset, or only some of the pixel openings may be selected to be offset. The specific design may be carried out according to an actual need. For a plurality of selected options, a corresponding structure of the display panel is described below in the following embodiments.

In the embodiments of the present disclosure, referring to FIG. 2 again, the plurality of light-emitting devices 200 include light-emitting devices with different emitting colors, such as the first-type light-emitting device 200a, the second-type light-emitting device 200b, and the third-type light-emitting device 200c. At the pixel opening 401 and isolation opening 301 of the light-emitting device 200 with every emitting color, the orthogonal projections on the baseplate 100 of at least two positions on the edge of the pixel opening 401 are at differing distances from the orthogonal projection of the edge of the isolation opening 301 on the baseplate 100. Thus, the pixel openings 401 corresponding to all the light-emitting devices 200 are offset, so as to reduce the impedance between the second electrodes 220 and the isolation structure 300 in the display panel.

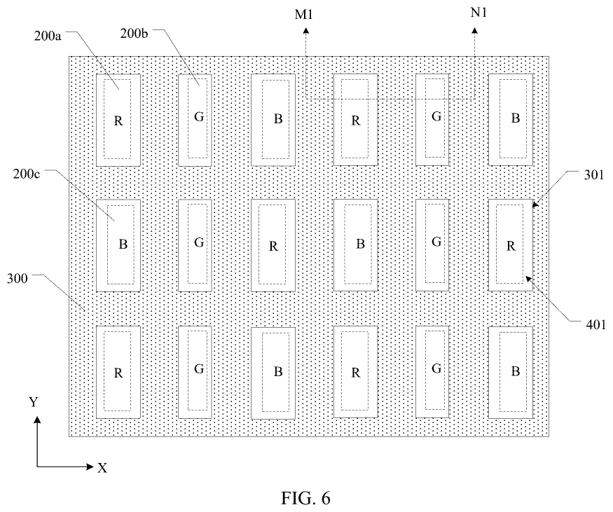

In at least one embodiment of the present disclosure, as shown in FIG. 6, the plurality of light-emitting devices 200 includes light-emitting devices with different emitting colors, such as the first-type light-emitting device 200a, the second-type light-emitting device 200b, and the third-type light-emitting device 200c. At the pixel opening 401 and isolation opening 301 of the light-emitting device 200 with at least one emitting color (for example, the second-type light-emitting device 200b and the third-type light-emitting device 200c) , orthogonal projections on the baseplate 100 of at least two positions on the edge of the pixel opening 401 are at differing distances from the orthogonal projection on the baseplate 100 of the edge of the isolation opening 301. And at the pixel opening 401 and isolation opening 301 of the light-emitting device 200 with at least one other emitting color (for example, the first-type light-emitting device 200a), the orthogonal projection on the baseplate 100 of at least two positions on the edge of the pixel opening 401 are at same distances from the orthogonal projection on the baseplate 100 of the edge of the isolation opening 301. Thus, only the pixel openings 401 corresponding to a part of the light-emitting device 200 are offset. Thus, the impedance between the second electrode 220 and the isolation structure 300 in a specific type of light-emitting device 200 may be adjusted according to a need of the pixel arrangement, and the like.

In the embodiments of the present disclosure, the term “the same distance” above-mentioned refers to the same value in theory (under an ideal condition during a structural design). In an actual manufacturing process, due to factors such as a process error, there may be an absolute error between two compared objects with “the same distance”. For example, the absolute error may be less than 1 μm. That is, when the absolute error is less than 1 μm, it is still considered that the compared objects are at “the same distance”. This case is only valid when the two compared objects are theoretically designed to have exactly the same distance during the design of the structure of the display panel. When the two compared objects (such as centroids corresponding to isolation opening 301 and pixel opening 401) have an “unequal” relationship (for example, distances of the two compared objects to a reference object are unequal, that is, there is an offset between the two compared objects) at an initial design stage, even when a range of the “unequal” relationship is less than 1 μm, the two compared objects are still regarded as having an “unequal” relationship.

In at least one embodiment of the present disclosure, as shown in FIG. 6, the plurality of light-emitting devices 200 includes light-emitting devices with different emitting colors, such as the first-type light-emitting device 200a, the second-type light-emitting device 200b, and the third-type light-emitting device 200c. The pixel openings 401 corresponding to the light-emitting devices 200 of at least two emitting colors (for example, the second-type light-emitting device 200b and the third-type light-emitting device 200c) include a first pixel opening projection edge 401a and a second pixel opening projection edge 401b. That is, the pixel openings 301 corresponding to a part of light-emitting devices 200 with some emitting colors are offset. For example, in FIG. 6, the pixel openings 301 corresponding to the second-type light-emitting device 200b and the third-type light-emitting device 200c are offset, and the pixel opening 301 corresponding to the first-type light-emitting device 200a is not offset.

In one example, as shown in FIG. 6, for the light-emitting devices 200 corresponding to the pixel openings 401 including the first pixel opening projection edge 401a and the second pixel opening projection edge 401b (for example, the second-type light-emitting device 200b and the third-type light-emitting device 200c), in the pixel openings 401 respectively corresponding to the light-emitting devices 200 with different emitting colors, directions from the first pixel opening projection edge 401a to the second pixel opening projection edge 401b are the same. That is, offset directions of pixel openings 401 relative to isolation openings 301 are the same (in FIG. 6, all are offset toward a right side, that is, a positive X-axis direction). Thus, the offset directions of the pixel openings 401 corresponding to the light-emitting devices 200 are the same, thereby reducing difficulty of a manufacturing process of the display panel and reducing a manufacturing cost of the display panel.

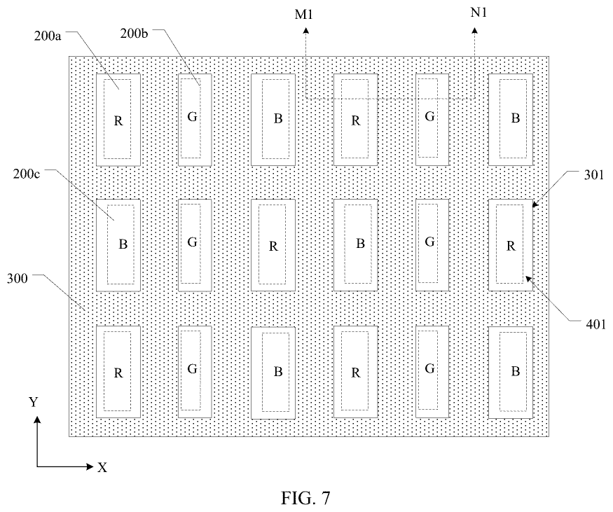

For example, in another example, as shown in FIG. 7, for the light-emitting devices 200 corresponding to the pixel openings 401 including the first pixel opening projection edge 401a and the second pixel opening projection edge 401b (for example, the second-type light-emitting device 200b and the third-type light-emitting device 200c), in the pixel openings 401 respectively corresponding to the light-emitting devices 200 with different emitting colors, directions from the first pixel opening projection edge 401a to the second pixel opening projection edge 401b are different. For example, the pixel openings 401 corresponding to the second-type light-emitting devices 200b have the same offset directions from the isolation opening 301 (as shown in FIG. 7, the pixel openings 401 corresponding to the second-type light-emitting devices 200b are offset toward the left, that is, in a negative X-axis direction). The pixel openings 401 corresponding to the third-type light-emitting devices 200c has the same offset directions from the isolation opening 301 (as shown in FIG. 7, the pixel openings 401 corresponding to the third-type light-emitting devices 200c are offset to the right, that is, in a positive X-axis direction). Different types of light-emitting devices 200 are manufactured in batches, and shapes and arrangement patterns of different types of light-emitting devices 200 may vary. In the embodiments, the offset direction of the pixel opening 401 corresponding to each type of light-emitting device 200 may be set according to an actual need, so as to reduce the impedance between the second electrode 220 of each type of light-emitting device 200 and the isolation structure 300.

In the embodiments of the present disclosure, degree of offset (a magnitude of an offset distance) of the pixel openings corresponding to different light-emitting devices is not limited. The specific design may be carried out according to an actual need. For a plurality of selected options, a corresponding structure of the display panel is described below in the following embodiments.

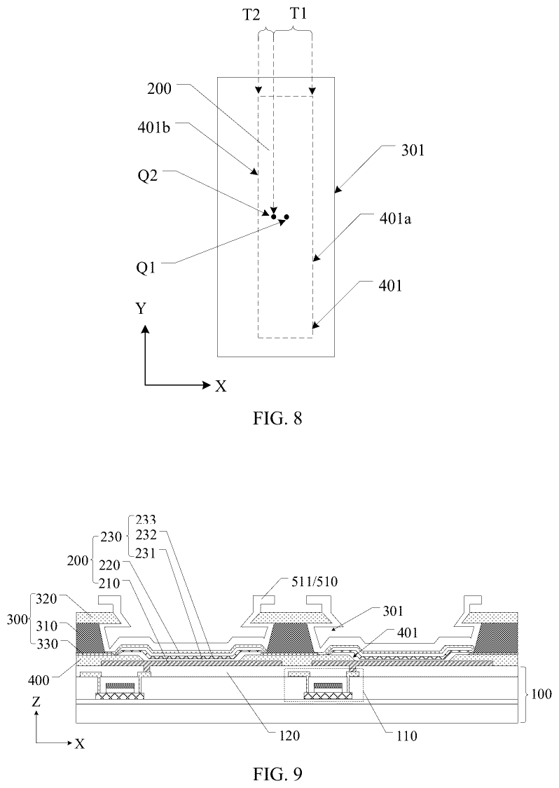

For example, in one instance, as shown in FIGS. 2 and 8, for the light-emitting devices 200 corresponding to the pixel openings 401 including the first pixel opening projection edge 401a and the second pixel opening projection edge 401b, in the pixel openings 401 respectively corresponding to the light-emitting devices 200 with different emitting colors, differences between a distance T1 from the first pixel opening projection edge 401a to a centroid Q2 of an orthogonal projection on the baseplate 100 of the isolation opening 301, and a distance T2 from the second pixel opening projection edge 401b to the centroid Q2 of the orthogonal projection on the baseplate 100 of the isolation opening 301 are equal. Thus, offset degree of the pixel openings 401 corresponding to the light-emitting devices 200 is the same, thereby reducing the difficulty of the manufacturing process of the display panel and reducing the manufacturing cost of the display panel.

In the embodiments of the present disclosure, the term “equal difference” above-mentioned refers to the same value in theory (under an ideal condition during a structural design). In an actual manufacturing process, due to factors such as a process error, there may be an absolute error between two compared objects with “equal difference”. For example, the absolute error may be less than 1 μm. That is, when the absolute error is less than 1 μm, the compared objects are still regarded as having a “same difference” relationship.

For example, in another instance, as shown in FIGS. 7 and 8, for the light-emitting devices 200 corresponding to the pixel openings 401 including the first pixel opening projection edge 401a and the second pixel opening projection edge 401b, in the pixel openings 401 respectively corresponding to the plurality of light-emitting devices 200 with different emitting colors, differences between the distance T1 from the first pixel opening projection edge 401a to the centroid Q2 of the orthogonal projection on the baseplate 100 of the isolation opening 301, and the distance T2 from the second pixel opening projection edge 401b to the centroid Q2 of the orthogonal projection on the baseplate 100 of the isolation opening 301 are different. For example, for the pixel openings 401 respectively corresponding to the second-type light-emitting device 200b and the third-type light-emitting device 200c, a difference in distance T1 and distance T2 at the pixel opening 401 corresponding to the third-type light-emitting device 200c is greater (greater offset degree). Different types of light-emitting devices 200 are manufactured in batches, and shapes and arrangement patterns of different types of light-emitting devices 200 may vary. In the embodiments, offset degree of the pixel opening 401 corresponding to each type of light-emitting device 200 may be set according to an actual need, so as to reduce the impedance between the second electrode 220 of each type of light-emitting device 200 and the isolation structure 300.

In the embodiments of the present disclosure, a specific design of the isolation structure and principle of the isolation structure isolating layers of the light-emitting devices are described below with reference to the accompanying drawings.

In at least one embodiment of the present disclosure, referring to FIG. 3A again, the light-emitting device 200 includes the first electrode 210, the light-emitting functional layer 230, and the second electrode 220 sequentially stacked on the baseplate 100. The light-emitting functional layer 230 and the second electrode 220 are located in a corresponding isolation opening 301. For example, the first electrode 210 may be configured as an anode, and the second electrode 220 may be configured as a cathode.

For example, the light-emitting functional layer 230 may include a first common layer 231, a light-emitting layer 232, and a second common layer 233. The first common layer 231, the light-emitting layer 232, and the second common layer 233 are sequentially stacked on the first electrode 210. The first common layer 231 may include a hole injection layer, a hole transport layer, an electron blocking layer, and the like. The second common layer 232 may include an electron injection layer, an electron transport layer, a hole blocking layer, and the like. The isolation structure 300 needs to be configured such that the first common layer 231 of each light-emitting device 200 (a main layer that causes current crosstalk) is electrically disconnected from each other.

In at least one embodiment of the present disclosure, referring to FIG. 3A again, the isolation structure 300 includes a supporting portion 310 and a crown portion 320. The supporting portion 310 is located between the crown portion 320 and the baseplate 100. An orthogonal projection on the baseplate 100 of an end, facing the crown portion 320, of the supporting portion 310, is located within an orthogonal projection on the baseplate 100 of the crown portion 320. Thus, during an evaporation of a layer of the light-emitting device 200 (such as the light-emitting functional layer 230 and the second electrode 220), the crown portion 320 may limit an evaporation range of the layer, so that some layers (such as the light-emitting functional layer 230) are isolated by the isolation structure 300, and other layers (such as the second electrode 220) are ensured to be connected to the isolation structure 300.

For example, an orthogonal projection on the baseplate 100 of the supporting portion 310 is located within the orthogonal projection on the baseplate 100 of the crown portion 320. Thus, a cross-sectional shape of a part of isolation structure 300 located between adjacent isolation openings 301 is approximately an inverted trapezoid, thereby enhancing isolation effect of isolation structure 300 on the layer of the light-emitting device 200. Specifically, during an evaporation of a layer (such as the light-emitting functional layer 230 and the second electrode 220) of the light-emitting device, an evaporation range of the layer may be limited by the crown portion 320, so that some layers (such as the light-emitting functional layer) are isolated by the isolation structure 300, and other layers (such as the second electrode 220) are ensured to be connected to the isolation structure 300.

For example, the isolation structure 300 is located on a side, facing away from the baseplate 100, of the pixel defining layer 400. Thus, the pixel defining layer 400 may cover each gap between the first electrodes 210, and may further cover edges of the first electrode 210 to prevent the isolation structure 300 from connecting with the first electrode 210.

In at least one embodiment of the present disclosure, referring to FIG. 3A again, the supporting portion 310 is a conductive structure, and the second electrode 222 is connected to a side surface of the supporting portion 310. Thus, the second electrodes 220 of each light-emitting device 200 are connected together through the supporting portion 310 to form a common electrode, and a thickness of the supporting portion 310 is not limited, thereby reducing the impedance of the common electrode.

A material of the second electrode 220 may be a metal material. The thinner the second electrode 220 is, the higher a light transmittance of the second electrode 220 may be, but the resistivity may be higher. When the thickness of the second electrode 220 is too small, without arranging the isolation structure 300, a voltage drop of the second electrode 220 (as a common electrode at this time) may be too large. In the embodiments of the present disclosure, the second electrode 220 is connected to the conductive supporting portion 310, so that thickness limitation of the second electrode 220 is eliminated, thereby enabling the second electrode 220 to have a less thickness to achieve a higher light transmittance.

For example, the pixel opening 401 of the pixel defining layer 400 confines the light-emitting device 200 and exposes the first electrode 210. That is, the edge of pixel opening 401 coincides with an edge of a light-emitting region of the corresponding light-emitting device 200. The pixel opening 401 corresponds one-to-one with the isolation opening 301, and pixel opening 401 is in communication with the corresponding isolation opening 301.

In the embodiments of the present disclosure, the term “coincide” above-mentioned refers to coincidence in theory (under an ideal condition during a structural design). In an actual manufacturing process, due to factors such as a process error, there may be an absolute error between two compared objects that are supposed to “coincide”. For example, the absolute error may be less than 1 μm. That is, when the absolute error is less than 1 μm, the compared objects are still regarded as coinciding with each other.

For example, the pixel defining layer 400 may be an inorganic layer. In a process of manufacturing the light-emitting device 200 based on the isolation structure 300, the pixel defining layer 400 does not require a relatively large thickness to accommodate the light-emitting device 200, thereby conducive to a thin and lightweight design of the display panel. Furthermore, the pixel defining layer 400 as an inorganic film may have a high bonding strength with the isolation structure 300 and the first electrode 210, thereby reducing a risk of the isolation structure 300 and the first electrode 210 falling off. In addition, a density of the inorganic layer is high, thereby more effectively preventing invasion of water and oxygen, and improving an encapsulation effect of the display panel. Moreover, when the pixel defining layer 400 is an inorganic layer, a thickness of the pixel defining layer 400 may be less, thereby reducing a step difference at the edge of the pixel opening 401. So that film continuity of the second electrode 220 at the edge of the pixel opening 401 is improved, the impedance of the second electrode 220 is reduced, and a display effect of the display panel is ensured.

In at least one embodiment of the present disclosure, as shown in FIG. 9, the isolation structure 300 further includes a bottom portion 330. The bottom portion 330 is located on a side, facing away from the crown portion 320, of the supporting portion 310, and the bottom portion 330 is a conductive structure. An orthogonal projection of the bottom portion 330 on baseplate 100 is located within an orthogonal projection of the crown portion 320 on baseplate 100, and an orthogonal projection of the supporting portion 310 on the baseplate 100 is located within the orthogonal projection of the bottom portion 330 on the baseplate 100. The second electrode 220 connects to a region, not covered by the supporting portion 310, of a surface, facing away from the baseplate 100, of the bottom portion 330. Compared with a side surface of the supporting portion 310, the second electrode 220 is deposited more easily on the bottom portion 330, thereby reducing impedance at a connection between the second electrode 220 and the isolation structure 300.

For example, the crown portion 320, the supporting portion 310 and the bottom portion 330 can be made sequentially from Ti, Al and Mo, thereby forming the isolation structure 300 as shown in FIG. 9.

In embodiments of the present disclosure, no limitation is placed on whether the first electrode 210 is offset relative to at least one of the following structure: the isolation opening 301 and the pixel opening 401. A specific design whether the first electrode 210 is offset relative to the structure may be carried out according to an actual need. Several exemplary ways of providing the first electrode 210 under these conditions are described below with reference to different embodiments.

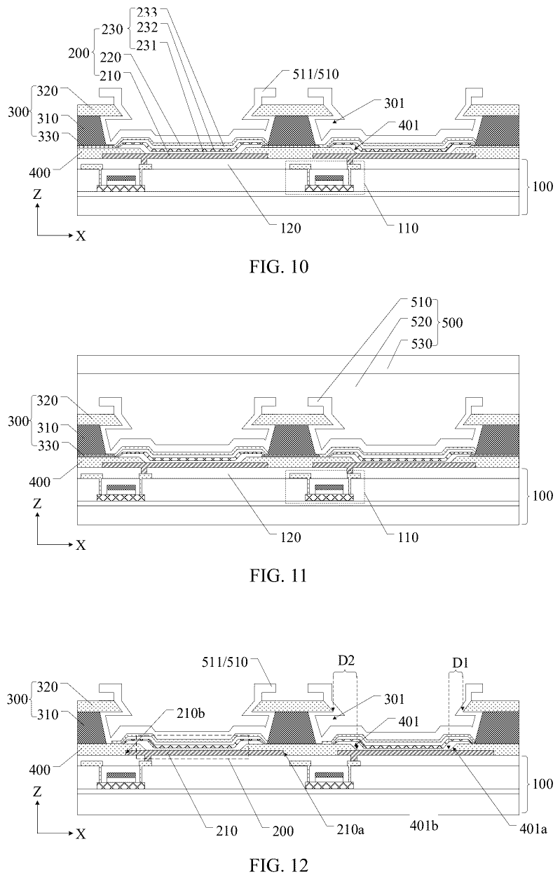

For example, in some embodiments of the present disclosure, as shown in FIG. 10, a centroid of an orthogonal projection on the baseplate 100 of the first electrode 210 may not be offset from a centroid of an orthogonal projection on the baseplate 100 of the isolation opening 301, but the centroid of the orthogonal projection on the baseplate 100 of the first electrode 210 may be offset from a centroid of an orthogonal projection of the pixel opening 401 on the baseplate 100. For example, a centroid of an orthogonal projection on the baseplate 100 of at least one first electrode 210 coincides with a centroid of an orthogonal projection on the baseplate 100 of the isolation opening 301, and the centroid of the orthogonal projection on the baseplate 100 of the at least one first electrode 210 is located outside a centroid of an orthogonal projection on the baseplate 100 of the pixel opening 401.

For example, in other embodiments of the present disclosure, referring to FIG. 3A or 9, the centroid of the orthogonal projection on the baseplate 100 of the first electrode 210 may be offset from the centroid of the orthogonal projection on the baseplate 100 of the isolation opening 301, but the centroid of the orthogonal projection on the baseplate 100 of the first electrode 210 may not be offset from the centroid of the orthogonal projection on the baseplate 100 of the pixel opening 401. For example, the centroid of the orthogonal projection on the baseplate 100 of the at least one first electrode 210 is located outside the centroid of the orthogonal projection on the baseplate 100 of the isolation opening 301, and the centroid of the orthogonal projection on the baseplate 100 of the at least one first electrode 210 coincides with the centroid of the orthogonal projection on the baseplate 100 of the pixel opening 401. Thus, alignment between the first electrode 210 and the pixel opening 401 is ensured, so that the pixel opening 401 lies entirely within the first electrode 210 and an effective light-emitting region of the light-emitting device 200 is guaranteed.

For example, in other embodiments of the present disclosure, the first electrode 210 may be offset relative to the isolation opening 301 and the pixel opening 401 (not shown in figures). For example, the centroid of the orthogonal projection on the baseplate 100 of the at least one first electrode 210 is located outside the centroid of the orthogonal projection on the baseplate 100 of the isolation opening 301, the centroid of the orthogonal projection on the baseplate 100 of the at least one first electrode 210 is located outside the centroid of the orthogonal projection on the baseplate 100 of the pixel opening 401, and the centroid of the orthogonal projection on the baseplate 100 of the isolation opening 301 is located outside the centroid of the orthogonal projection on the baseplate 100 of the pixel opening 401.

In embodiments of the present disclosure, no limitation is placed on whether the second electrode 220 is offset relative to at least one of the following structure: the isolation opening 301 and the pixel opening 401. A specific design whether the second electrode 220 is offset relative to the structure may be carried out according to an actual need. Several exemplary ways of providing the second electrode 220 under these conditions are described below with reference to different embodiments.

For example, in some embodiments of the present disclosure, referring to FIG. 3A again, a centroid of the at least one second electrode 220 coincides with a centroid of the isolation opening 301. For a specific structure of the display panel in this case, reference may be made to the relevant description of the aforementioned embodiments shown in FIG. 3A, and the structure may not be repeated here.

For example, in other embodiments of the present disclosure, referring to FIG. 5 again, the first pixel opening projection edge 401a corresponds to a first side of the isolation opening 301. The second pixel opening projection edge 401b corresponds to a second side of the isolation opening 301. The second electrode 220 overlaps the isolation structure 300 on the first side. A gap is provided between the second electrode 220 and the isolation structure 300 on the second side. A centroid, of an orthogonal projection on the baseplate 100 of the second electrode 220, is located between a centroid of an orthogonal projection of the isolation opening 301 on the baseplate 100 and the first pixel opening projection edge 401a. For a specific structure of the display panel in this case, reference may be made to the relevant aforementioned description of the embodiment shown in FIG. 5, and the structure may not be repeated here. For example, furthermore, a centroid, of the orthogonal projection on the baseplate 100 of the pixel opening 401, is located between the centroid of the orthogonal projection on the baseplate 100 of the second electrode 220 and the first pixel opening projection edge 401a. That is, when the pixel opening 401 and the second electrode 220 are offset in the same direction relative to the isolation opening 301, an offset distance of the pixel opening 401 relative to the isolation opening 301 is greater than an offset distance of the second electrode 220 relative to the isolation opening 301.

In at least one embodiment of the present disclosure, as shown in FIG. 10, the display panel further includes a first encapsulation layer 510. The first encapsulation layer 510 includes encapsulation units 511 respectively covering the plurality of light-emitting devices 200. A centroid of an orthogonal projection on the baseplate 100 of the encapsulation unit 511 coincides with the centroid of the orthogonal projection on the baseplate 100 of the isolation opening 301. The light-emitting devices 200 are manufactured in batches based on emitting colors, and the encapsulation units 511 are formed in batches together with the light-emitting devices 200, so that already-produced light-emitting devices 200 are protected throughout the entire manufacturing process.

During the manufacturing process of the light-emitting device, the encapsulation unit 511 may undergo etching, resulting in a possibility that a partial region of the encapsulation unit 511 may be etched through. In this case, the second electrode 220 may resist the etching process. If a thickness of the second electrode 220 is relatively small, there is a risk that the second electrode 220 may be etched through, further causing damage to the underlying pixel defining layer 400 through the etching process. The embodiments of the present disclosure may solve the problem. For a specific structure and principle involved, reference may be made to the relevant description of the above-mentioned embodiment, and the structure and principle may not be repeated here.

In at least one embodiment of the present disclosure, as shown in FIG. 10, an edge of the encapsulation unit 511 extends to a side, facing away from the baseplate 100, of the crown portion 320, and a part of the encapsulation unit 511, located on a side, facing away from the baseplate 100, of the crown portion 320 is spaced apart from the crown portion 320 to form an overhanging portion. Formation of the overhanging portion is related to the manufacturing process of the light-emitting device 200 based on the isolation structure 300.

In at least one embodiment of the present disclosure, as shown in FIG. 11, the encapsulation structure 500 may further include a second encapsulation layer 520 and a third encapsulation layer 530 both covering the first encapsulation layer 510 and the isolation structure 300. The second encapsulation layer 520 is located between the first encapsulation layer 510 and the third encapsulation layer 530. For example, the first encapsulation layer 510 and the third encapsulation layer 530 are inorganic layers, and a density of the inorganic layer is high so that the inorganic layer can prevent water and oxygen from penetrating. The second encapsulation layer 520 is an organic layer serving as a planarization layer, thus having a relatively large thickness to flatten a surface of the display panel, facilitating manufacturing of functional structures such as a touch structure, an optical film, and a cover on the encapsulation structure 500.

In the embodiments of the present disclosure, the pixel opening 401 is actually configured to define a light-emitting region of the light-emitting device 200. Therefore, the offset of pixel opening 401 is actually equivalent to the offset of the light-emitting region of the light-emitting device 200. A range of the light-emitting region of the light-emitting device 200 is also related to the first electrode 210 of the light-emitting device 200. A region, in which the first electrode 210 coincides with pixel opening 401, constitutes the light-emitting region of the light-emitting device 200. Therefore, whether the first electrode 210 is offset and offset degree of the first electrode 210 may affect degree of coincidence between the first electrode 210 and the pixel opening 401, thereby determining whether the light-emitting region of the light-emitting device 200 is offset and the offset degree.

A specific structure of the display panel is described in detail from a standpoint of a positional relationship among the first electrode 210, the isolation opening 301 and the pixel opening 401 as follows.

In at least one embodiment of the present disclosure, referring to FIG. 3A again, at at least one isolation opening 301, a centroid (covered by the isolation structure), of an orthogonal projection on the baseplate 100 of a gap between adjacent first electrodes 210, is located outside a centroid of an orthogonal projection on the baseplate 100 of the isolation opening 301. Thus, the first electrode 210 may be offset along with the pixel opening 401 (an offset direction and an offset magnitude of the first electrode 210 and an offset direction and an offset magnitude of the pixel opening 401 can be the same or different), so as to adjust a distribution of a part of the pixel defining layer 400 that covers an edge of the first electrode 210 (the part may be raised by the first electrode 210), and to adjust impedance at connections of the second electrode 220 and the isolation structure 300 at different positions.

In at least one embodiment of the present disclosure, referring to FIG. 5 again, a centroid of an orthogonal projection on the baseplate 100 of a part of the isolation structure 300, located between a gap of two adjacent isolation openings 301, is located outside a centroid of an orthogonal projection on the baseplate 100 of a gap between the first electrodes 210 corresponding to the two adjacent isolation openings 301. For example, in this case, a centroid of an orthogonal projection on the baseplate 100 of the first electrode 210 is located outside the centroid of the orthogonal projection on the baseplate 100 of the isolation opening 301. That is, the first electrode 210 is offset relative to the corresponding isolation opening 301. Thus, while the first electrode 210 is ensured to be offset from the isolation opening 301, parameters of the isolation structure 300 (for example, a width between the adjacent isolation openings 301, and the like) do not need to be changed, so as to ensure a pixel density of the display panel.

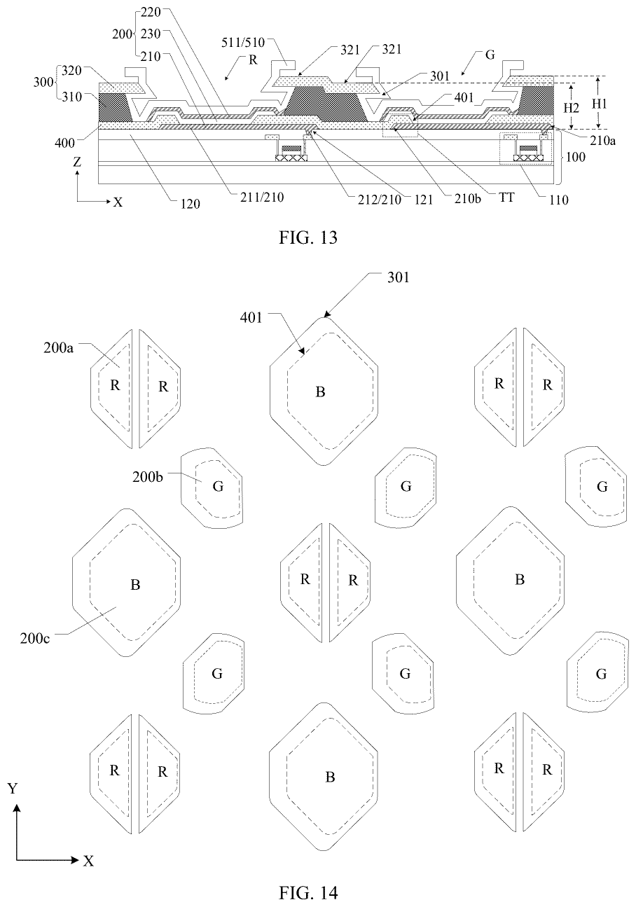

In at least one embodiment of the present disclosure, as shown in FIGS. 12 and 13, at the isolation opening 301 with a centroid offset from the first electrode 210, the first electrode 210 includes a first electrode edge 210a and a second electrode edge 210b opposite to each other. An orthogonal projection on the baseplate 100 of the first electrode edge 210a, is located within an orthogonal projection on the baseplate 100 of the isolation structure 300. An orthogonal projection on the baseplate 100 of the second electrode edge 210b is located outside the orthogonal projection of the isolation structure 300 on the baseplate 100, and the orthogonal projection on the baseplate 100 of the second electrode edge 210b is located within the orthogonal projection on the baseplate 100 of the isolation opening 301. Thus, on a side of the first electrode edge 210a, a part, of the pixel defining layer 400 raised by the first electrode 210, may extend below the isolation structure 300, further improving a film-forming condition for the second electrode 220 on a side of the first electrode edge 210a, and promoting a connection between the second electrode 220 and the isolation structure 300, thereby reducing the impedance between the second electrode 220 and the isolation structure 300 on a side on which the first-electrode edge 210a is located.

A difference between the display panels shown in FIGS. 12 and 13 lies in the following. During a manufacturing process of the display panel, a gap is considered to be provided between the first electrodes 210. When the pixel defining layer 400 and the isolation structure 300 are formed subsequently, a part, covering the gap between the first electrode 210, of layers configured to form the pixel defining layer 400 and the isolation structure 300 conforms to the gap, thus presenting a structure as shown in FIG. 13.

In at least one embodiment of the present disclosure, as shown in FIG. 13, the first electrode 210 includes a main body portion 211 and a connecting portion 212 connected with the main body portion 211. The main body portion 211 includes the first electrode edge 210a and the second electrode edge 210b above mentioned. An orthogonal projection on the baseplate 100 of the connecting portion 212 is located within an orthogonal projection on the baseplate 100 of the isolation structure 300. Thus, the connecting portion 212 is hidden below the isolation structure 300, thereby not affecting film formation quality (such as flatness) of other layers of the light-emitting device 200 in the isolation opening 301, ensuring the quality of the light-emitting device 200.

In embodiments of the present disclosure, as shown in FIG. 13, the baseplate 100 may include a substrate and a driving circuit layer located on the substrate. The driving circuit layer includes a plurality of pixel driving circuits (for example, a pixel circuit layer mentioned below) located in the display region. The light-emitting devices 200 are located on a side, facing away from the substrate, of the driving circuit layer. For example, the pixel driving circuit may include a plurality of Thin-Film Transistors (TFTs), capacitors, and the like. The pixel driving circuit may be formed in various configurations such as 2T1C (two TFTs and one capacitor (C)), 3T1C, 7T1C, or the like. The pixel driving circuits are connected to the light-emitting devices 200 in a display functional layer to control an on-off states and emission brightness of the light-emitting devices 200.

In at least one embodiment of the present disclosure, as shown in FIG. 13, the baseplate 100 includes a pixel circuit layer 110 (one of the TFTs is shown) and a planarization layer 120. The planarization layer 120 is located between the pixel circuit layer 110 and the first electrode 210. The planarization layer 120 is provided with a via 121, the connecting portion 212 is located in the via 121, to make the main body portion 211 of the first electrode 210 be electrically connected to the pixel circuit layer 110 through the via 121 and the connecting portion 212.

In at least one embodiment of the present disclosure, as shown in FIG. 13, a distance H1 is a distance between the baseplate 100 and a surface, facing away from the baseplate 100, of a part of the isolation structure 300 on a side on which the first electrode edge 210a is located. A distance H2 is a distance between the baseplate 100 and a surface, facing away from the baseplate 100, of a part of the isolation structure 300 on a side on which the second electrode edge 210b is located. The position of the first electrode 210 may be adjusted, so that the distance H1 is greater than the distance H2.

In at least one embodiment of the present disclosure, as shown in FIG. 13, for a part of the isolation structure 300 located between two adjacent isolation openings 301, a distance H1 between the baseplate 100 and a surface, facing away from the baseplate 100, of a part, adjacent to one of the adjacent isolation openings 301 (for example, the isolation opening 301 on the left), of the isolation structure 300, is greater than a distance H2 between the baseplate 100 and a surface, facing away from the baseplate 100, of a part, adjacent to the other isolation opening 301 (for example, the isolation opening 301 on the right), of the isolation structure 300.

In at least one embodiment of the present disclosure, as shown in FIG. 13, an orthogonal projection on the baseplate 100 of the part of the isolation structure 300 on the side on which the first electrode edge 210a is located, is located within an orthogonal projection on the baseplate 100 of the first electrode 210. An orthogonal projection of the part of the isolation structure 300 on the side on which the second electrode edge 210b is located, is located outside the orthogonal projection on the baseplate 100 of the first electrode 210. Thus, the first electrode edge 210a of the first electrode 210 extends below the isolation structure 300, and the second electrode edge 210b of the first electrode 210 does not extend below the isolation structure 300. As a result, with elevated effect of the first electrode 210, the structure as shown in FIG. 13 is obtained.

In at least one embodiment of the present disclosure, as shown in FIG. 13, a surface, facing away from the baseplate 100, of the isolation structure 300 includes a first region 321 and a second region 322 with different distances from the baseplate 100. In the first region 321 and the second region 322, an orthogonal projection on the baseplate 100 of a region with a greater distance to the baseplate 100 (for example, the first region 321) overlaps with the orthogonal projection on the baseplate 100 of the first electrode 210, and an orthogonal projection on the baseplate 100 of a region with a less distance to the baseplate 100 (for example, the second region 322) is outside the orthogonal projection on the baseplate 100 of the first electrode 210.

In at least one embodiment of the present disclosure, as shown in FIG. 13, the light-emitting functional layer 230 and the second electrode 220 of the light-emitting device 200 are confined in the isolation opening 301 and the pixel opening 401. An edge part of the first electrode 210 is located between the pixel defining layer 400 and the baseplate 100. On a side on which the second electrode edge 210b is located, a part of the pixel defining layer 400 covering the first electrode 210 constitutes a stepped structure TT. An orthogonal projection on the baseplate 100 of the stepped structure TT is located within an orthogonal projection on the baseplate 100 of the isolation opening 301.

In at least one embodiment of the present disclosure, as shown in FIG. 13, under elevation effect of the first electrode, a distance, between the baseplate 100 and an edge of the light-emitting functional layer 230 on a side on which the first electrode edge 210a is located, is greater than a distance between the baseplate 100 and an edge of the light-emitting functional layer 230 on a side on which the second electrode edge 210b is located. In at least one embodiment of the present disclosure, as shown in FIG. 13, under elevation effect of the first electrode, the display panel further includes a first encapsulation layer 510 covering the isolation opening 301. The first encapsulation layer 510 includes encapsulation units 511 covering the light-emitting devices 200 respectively. A distance between the baseplate 100 and an edge of the encapsulation unit 511 on the side on which the first electrode edge 210a is located, is greater than a distance between the baseplate 100 and an edge of the encapsulation unit 511 on the side on which the second electrode edge 210b is located.

In at least one embodiment of the present disclosure, as shown in FIG. 13, the second electrode 220 overlaps one of two opposite side walls of the isolation structure 300 (a side wall of the isolation structure 300 corresponding to the first electrode edge 210a), and a gap is provided between the second electrode 220 and the other side wall (a side wall of the isolation structure 300 corresponding to the second electrode edge 210b).

In at least one embodiment of the present disclosure, as shown in FIG. 13, in a case where the first electrode 210 is offset relative to the isolation opening 301, the second electrode 220 overlaps the isolation structure 300 on a side on which the first electrode edge 210a is located, and gap is provided between the second electrode 220 and the isolation structure 300 on a side on which the second electrode edge 210b is located, thereby achieving a single-side overlap between the second electrode 220 the isolation structure 300.

In at least one embodiment of the present disclosure, as shown in FIGS. 13 and 14, in a case where the first electrode 210 is offset relative to the isolation opening 301, the light-emitting devices 200 include light-emitting devices 200 with different emitting colors, such as the first-type light-emitting device 200a, the second-type light-emitting device 200b, and the third-type light-emitting device 200c. For each of the light-emitting device 200 with the same emitting color, a position in which the second electrode 220 overlaps a side wall of the isolation structure 300 is on the same side of the isolation opening 301. Thus, offset directions of the second electrodes 220 corresponding to the light-emitting devices 200 of the same emitting color are the same, thereby reducing the difficulty of the manufacturing process of the display panel and reducing the manufacturing cost of the display panel.

In at least one embodiment of the present disclosure, as shown in FIG. 14, the light-emitting devices 200 of at least one emitting color include first-type light-emitting devices 200a and third-type light-emitting devices 200c. A figure formed by splicing orthogonal projections on the substrate 100 of at least two adjacent first-type light-emitting devices 200a is the same in shape as an orthogonal projection on the substrate 100 of one third-type light-emitting device 200c. For all the first-type light-emitting device 200a and all the third-type light-emitting device 200c, a position in which the second electrode 220 overlaps with the isolation structure 300 is on the same side as the isolation opening 301.

In at least one embodiment of the present disclosure, as shown in FIG. 14, the plurality of light-emitting devices 200 include light-emitting devices 200 with different emitting colors, such as the first-type light-emitting device 200a, the second-type light-emitting device 200b, and the third-type light-emitting device 200c. For each of the light-emitting devices 200 with different emitting colors (for example, the first-type light-emitting device 200a and the third-type light-emitting device 200c), a direction, from a side wall of the isolation structure 300 overlapped by the second electrode 220 to a side wall of the isolation structure 300 with a gap from the second electrode 220, is the same. Thus, offset directions of the second electrodes 220 corresponding to all the light-emitting devices 200 are the same, thereby further reducing the difficulty of the manufacturing process of the display panel, and reducing the manufacturing cost of the display panel.

In at least one embodiment of the present disclosure, referring to FIG. 7 again, in a case where the second electrode 220 is in single-side overlap with the isolation structure 300, for light-emitting devices 200 with different emitting colors (such as the second-type light-emitting device 200b and the third-type light-emitting device 200c), directions from the side wall of the isolation structure 300 overlapped by the second electrode 220 to the side wall of the isolation structure 300 with the gap from the second electrode 220, are different. Different types of light-emitting devices 200 are manufactured in batches, and shapes and arrangement patterns of different types of light-emitting devices 200 may vary. In this embodiment, the offset direction of the second electrode 220 of light-emitting device 200 of each type may be configured according to an actual need, so as to reduce the impedance between the second electrode 220 of light-emitting device 200 of each type and the isolation structure 300.

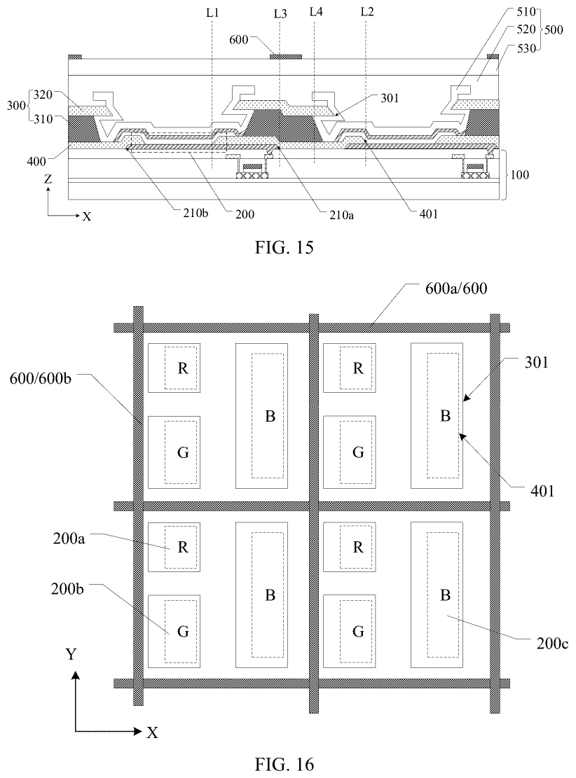

In at least one embodiment of the present disclosure, as shown in FIG. 15, the display panel may further include a touch function layer 600. The touch function layer 600 is located on a side, facing away from the baseplate 100, of the isolation structure 300. The touch function layer 600 constitutes a first mesh pattern. The pixel defining layer 400 constitutes a second mesh pattern, and the pixel opening 401 is a mesh hole of the second mesh pattern. The first mesh pattern and the second mesh pattern both include a plurality of mesh lines. An orthogonal projection on the baseplate 100 of a centerline of at least one mesh line of the first mesh pattern, coincides with an orthogonal projection on the baseplate 100 of a centerline of at least one mesh line of the second mesh pattern. For example, for a part of isolation structure 300 located between adjacent isolation openings 301, boundaries (closest to the isolation structure 300) of the pixel openings 401 located on two sides of the isolation structure 300 correspond to a line L1 and a line L2. The line L1 and line L2 are perpendicular to the baseplate 100, and a distance between a mesh line of the touch function layer 600 and line L1 is equal to a distance between the mesh line of the touch function layer 600 and line L2.

In at least one embodiment of the present disclosure, as shown in FIG. 15, gaps between the first electrodes 210 constitute a third mesh pattern, and the third mesh pattern includes a plurality of mesh lines. The orthogonal projection on the baseplate 100 of the centerline of the at least one mesh line of the first mesh pattern, is located outside an orthogonal projection on the baseplate 100 of a centerline of at least one mesh line of the third mesh pattern. For example, a center of the gap of adjacent first electrodes 210 is located on a line L4, and the line L4 is perpendicular to the baseplate 100. A center of the mesh line of the touch function layer 600 is not located on the line L4.

In at least one embodiment of the present disclosure, as shown in FIG. 15, an orthogonal projection on the baseplate 100 of a center of at least one mesh line of the touch function layer 600, is located outside an orthogonal projection on the baseplate 100 of a center of the part of isolation structure 300 located between adjacent isolation openings 301. For example, the center, of the part of the isolation structure 300 located between the adjacent isolation openings 301, is located on a line L3. The line L3 is perpendicular to the baseplate 100. The center of the mesh line of the touch function layer 600 is not located on line L3.

In at least one embodiment of the present disclosure, as shown in FIG. 15, the display panel may further include a touch function layer 600. The touch function layer 600 is located on a side, facing away from the baseplate 100, of the isolation structure 300. The touch function layer 600 constitutes a first mesh pattern. Gaps between the first electrodes 210 constitute a third mesh pattern. The first mesh pattern and the third mesh pattern both include a plurality of mesh lines. An orthogonal projection on the baseplate 100 of the first mesh pattern, is located within an orthogonal projection on the baseplate 100 of the isolation structure 300. An orthogonal projection on the baseplate 100 of a centerline of at least a part of the mesh lines of the first mesh pattern, is located outside an orthogonal projection on the baseplate 100 of a centerline of the mesh line of the third mesh pattern.

In at least one embodiment of the present disclosure, as shown in FIGS. 15 and 16, the mesh lines of the first mesh pattern constituted by the touch function layer 600 includes a first-type mesh line 600a extending along a first direction (for example, a direction of an X-axis) and a second-type mesh line 600b extending along a second direction (for example, a direction of a Y-axis). The mesh lines of the third mesh pattern constituted by the gaps between the first electrodes 210 include a third-type mesh line extending along the first direction and a fourth type mesh line extending along the second direction. The first direction intersects with the second direction. An orthogonal projection on the baseplate 100 of a centerline of the first-type mesh line 600a coincides with an orthogonal projection on the baseplate 100 of a centerline of the third-type mesh line. An orthogonal projection on the baseplate 100 of a centerline of the second-type mesh line 600b is located outside an orthogonal projection on the baseplate 100 of a centerline of the fourth type mesh line.

In at least one embodiment of the present disclosure, as shown in FIGS. 15 and 16, a distance, between an orthogonal projection on the baseplate 100 of the second-type mesh line 600b and an orthogonal projection on the baseplate 100 of the first electrode edge 210a, is less than a distance between the orthogonal projection on the baseplate 100 of the second-type mesh line 600b and an orthogonal projection on the baseplate 100 of the second electrode edge 210b.

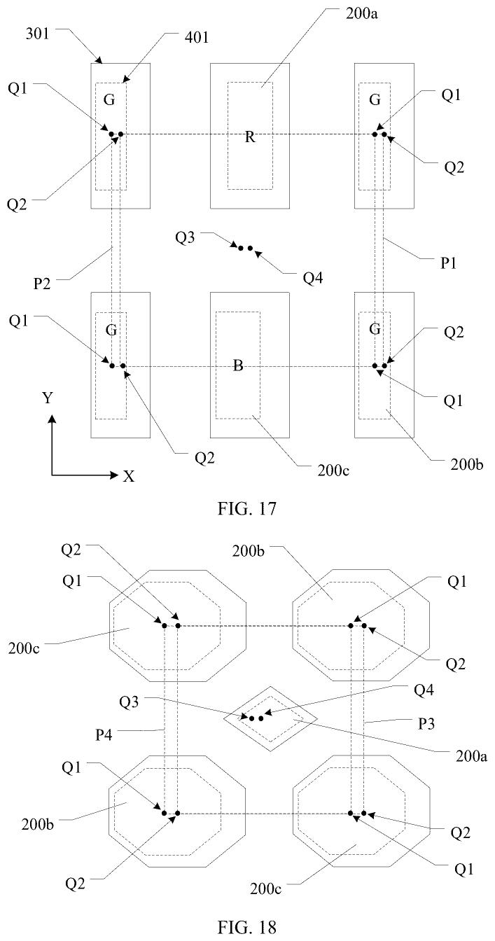

In at least one embodiment of the present disclosure, as shown in FIG. 17, the light-emitting devices 200 include first-type light-emitting devices 200a, second-type light-emitting devices 200b, and third-type light-emitting devices 200c with different emitting colors. The first-type light-emitting devices 200a, the second-type light-emitting devices 200b, and the third-type light-emitting devices 200c are arranged in a plurality of rows and a plurality of columns. The first-type light-emitting device 200a, the second-type light-emitting device 200b, and the third-type light-emitting device 200c are arranged in the same row, and the first-type light-emitting device 200a, the second-type light-emitting device 200b, and the third-type light-emitting device 200c are arranged in a periodic sequence along the row direction. The first-type light-emitting device 200a and the third-type light-emitting device 200c are arranged in the same column. Columns in which the first-type light-emitting device 200a and the third-type light-emitting device 200c are located, alternate with columns in which the second-type light-emitting device 200b is located. The four second-type light-emitting devices 200b, located at an M-th row and an N-th column, an (M+1)-th row and an N-th column, an M-th row and an (N+2)-th column, and an (M+1)-th row and an (N+2)-th column, constitute a first light-emitting device group. Centroids Q2 of the isolation openings 301 corresponding to the light-emitting devices 200 in the first light-emitting device group are vertices of a first virtual quadrilateral P1. Centroid Q1 of the pixel openings 401 corresponding to the first light-emitting device group are vertices of a second virtual quadrilateral P2. The first virtual quadrilateral P1 and the second virtual quadrilateral P2 are incompletely coincident. A centroid Q4 of the first virtual quadrilateral P1 is located outside a centroid Q3 of the second virtual quadrilateral P2. M and N are positive integers. Under this pixel arrangement, the pixel opening 401 corresponding to the light-emitting device 200 can be offset conveniently, a high pixel arrangement density PPI is ensured, and impedance between the second electrode 220 and the isolation structure 300 in the entire display panel is further reduced.

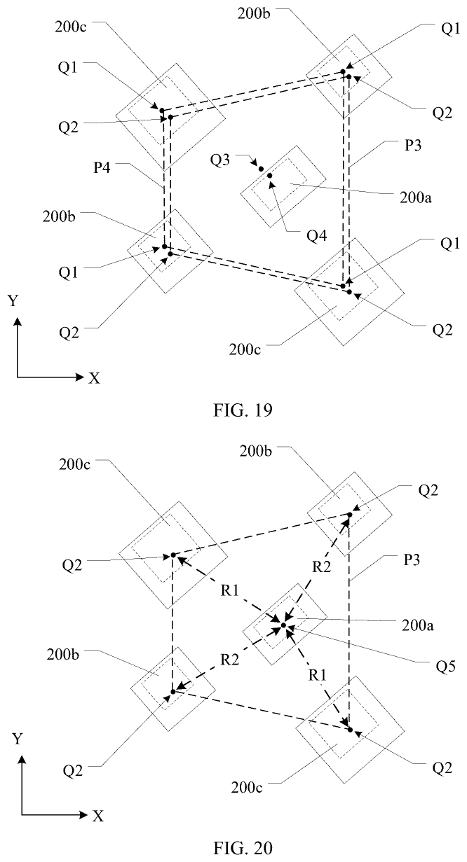

In at least one embodiment of the present disclosure, as shown in FIGS. 18 and 19, the light-emitting devices 200 include first-type light-emitting devices 200a, second-type light-emitting devices 200b and third-type light-emitting devices 200c with different emitting colors. The first-type light-emitting devices 200a, the second-type light-emitting devices 200b, and the third-type light-emitting devices 200c are arranged in a plurality of pixel units. Each pixel unit includes one first-type light-emitting device 200a, two second-type light-emitting devices 200b, and two third-type light-emitting devices 200c. In each pixel unit, centroids Q2 of orthogonal projections on the baseplate 100 of the isolation openings 301 corresponding to the two second-type light-emitting devices 200b, are located at first vertices of a third virtual quadrilateral P3, and centroids Q2 of orthogonal projections on the baseplate 100 of the isolation openings 301 corresponding to the two third-type light-emitting devices 200c, are located at second vertices of the third virtual quadrilateral P3. In each pixel unit, the first vertices and second vertices alternate and are spaced apart. An orthogonal projection on the baseplate 100 of the isolation opening 301 corresponding to the first-type light-emitting device 200a is located within the third virtual quadrilateral P3. Centroids Q1 of orthogonal projections on the baseplate 100 of the pixel openings 401 corresponding to two second-type light-emitting devices 200b and two third-type light-emitting devices 200c of the pixel unit are vertices of a fourth virtual quadrilateral P4. The third virtual quadrilateral P3 and the fourth virtual quadrilateral P4 are incompletely coincident. A centroid Q4 of the third virtual quadrilateral P3 is located outside a centroid Q3 of the fourth virtual quadrilateral P4. Under this pixel arrangement, the pixel opening 401 corresponding to the light-emitting device 200 can be offset conveniently, a high pixel arrangement density PPI is ensured, the impedance between the second electrode 220 and the isolation structure 300 in the entire display panel is further reduced. In the present disclosure, the two virtual quadrilaterals are incompletely coincident refers to that a part of four sides of the two virtual quadrilaterals do not coincide, or that all four sides of the two virtual quadrilaterals do not coincide at all.

In at least one embodiment of the present disclosure, as shown in FIG. 20, in the third virtual quadrilateral P3, first distances R1 between a centroid Q5 of an orthogonal projection on the baseplate 100 of the isolation opening 301 corresponding to the first-type light-emitting device 200a and a centroid Q2 of an orthogonal projection on the baseplate 100 of the isolation opening 301 corresponding to any third-type light-emitting device 200c are equal. In the third virtual quadrilateral P3, second distances R2 between the centroid Q5 of the orthogonal projection on the baseplate 100 of the isolation opening 301 corresponding to the first-type light-emitting device 200a and a centroid Q2 of an orthogonal projection on the baseplate 100 of the isolation opening 301 corresponding to any second-type light-emitting device 200b are equal. And the first distance R1 equals the second distance R2. At least one embodiment of the present disclosure provides a display panel. The display panel includes a baseplate 100, and an isolation structure 300, a pixel defining layer 400, and a plurality of light-emitting devices 200 located on the baseplate 100. The light-emitting device 200 includes a first electrode 210, a light-emitting functional layer 230, and a second electrode sequentially stacked on the baseplate 100. The isolation structure 300 includes a plurality of isolation openings 301. The light-emitting functional layer 230 and the second electrode 220 of the light-emitting device 200 are confined in the isolation opening 301. At at least one isolation opening 301, a centroid of an orthogonal projection on the baseplate 100 of the first electrode 210, is located outside a centroid of an orthogonal projection on the baseplate 100 of the isolation opening 301. In the display panel, the first electrode 210 may be offset together with the pixel opening 401 (an offset direction and an offset magnitude of first electrode 210 and an offset direction and an offset magnitude of the pixel opening 401 may be the same or different), so as to adjust a distribution of a part of the pixel defining layer 400 that covers an edge of the first electrode 210(the part may be raised by the first electrode 210), and to adjust impedance at connections of the second electrode and the isolation structure at different positions. For the structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, the display panel may further include a pixel defining layer 400 located between the baseplate 100 and the isolation structure 300. The pixel defining layer 400 includes a pixel opening 401 communicated with the isolation opening 301. The light-emitting functional layer 230 and the second electrode 220 of the light-emitting devices 200 are confined in the isolation opening 301 and the pixel opening 401. The centroid of the orthogonal projection on the baseplate 100 of the first electrode 210, is located outside a centroid of an orthogonal projection on the baseplate 100 of the pixel opening 401. For the structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, at the isolation opening 301 with a centroid offset from the first electrode 210, the first electrode 210 includes a first electrode edge 210a and a second electrode edge 210b opposite to each other. An orthogonal projection on the baseplate 100 of the first electrode edge 210a, is located within an orthogonal projection on the baseplate 100 of the isolation structure 300. An orthogonal projection on the baseplate 100 of the second electrode edge 210b, is located outside the orthogonal projection of the isolation structure 300 on the baseplate 100, and the orthogonal projection on the baseplate 100 of the second electrode edge 210b, is located within the orthogonal projection on the baseplate 100 of the isolation opening 301. For the structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, the first electrode 210 includes a connecting portion 212. The connecting portion 212 is adjacent to the first electrode edge 210a. An orthogonal projection on the baseplate 100 of the connecting portion 212 is located within the orthogonal projection on the baseplate 100 of the isolation structure 300. For the structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, the baseplate 100 includes a pixel circuit layer 110 and a planarization layer 120. The planarization layer 120 is located between the pixel circuit layer 110 and the first electrode 210. The planarization layer 120 is provided with a via 121. The connecting portion 212 is located in the via 121, to make the main body portion 211 of the first electrode 210 be electrically connected to the pixel circuit layer 110 through the via 121 and the connecting portion 212. For the structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, a distance between the baseplate 100 and a surface, facing away from the baseplate 100, of a part of the isolation structure 300 on a side on which the first electrode edge 210a is located, is greater than a distance between the baseplate 100 and a surface, facing away from the baseplate 100, of a part of the isolation structure 300 on a side on which the second electrode edge 210b is located. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, for a part of the isolation structure 300 located between two adjacent isolation openings 301, a distance between the baseplate 100 and a surface, facing away from the baseplate 100, of a part, adjacent to one of the adjacent isolation openings 301, of the isolation structure 300, is greater than a distance between the baseplate 100 and a surface, facing away from the baseplate 100, of a part, adjacent to the other isolation opening 301, of the isolation structure 300. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, an orthogonal projection on the baseplate 100 of the part of the isolation structure 300 on the side on which the first electrode edge 210a is located, is located within an orthogonal projection on the baseplate 100 of the first electrode 210. An orthogonal projection of the part of the isolation structure 300 on the side on which the second electrode edge 210b is located, is located outside the orthogonal projection on the baseplate 100 of the first electrode 210. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, a surface, facing away from the baseplate 100, of the isolation structure 300 includes a first region 321 and a second region 322 with different distances from the baseplate 100. In the first region 321 and the second region 322, an orthogonal projection on the baseplate 100 of a region with a greater distance to the baseplate 100 overlaps with the orthogonal projection on the baseplate 100 of the first electrode 210, and an orthogonal projection on the baseplate 100 of a region with a less distance to the baseplate 100 is outside the orthogonal projection on the baseplate 100 of the first electrode 210. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, a centroid of an orthogonal projection on the baseplate 100 of the first electrode 210, is offset relative to a centroid of an orthogonal projection on the baseplate 100 of the second electrode 220. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, the second electrode 220 overlaps the isolation structure 300 on a side on which the first electrode edge 210a is located, and a gap is provided between the second electrode 220 and the isolation structure 300 on a side on which the second electrode edge 210b is located. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, the centroid of the orthogonal projection on the baseplate 100 of the first electrode 210, is located between the centroid of the orthogonal projection on the baseplate 100 of the second electrode 220 and the orthogonal projection on the baseplate 100 of the first electrode edge 210a. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, the display panel further includes a first encapsulation layer 510 covering the isolation opening 301. The first encapsulation layer 510 includes encapsulation units 511 covering the light-emitting devices 200 respectively. At the isolation opening 301 with a centroid offset from the first electrode 210, the centroid of the orthogonal projection on the baseplate 100 of the first electrode 210 is offset relative to a centroid of an orthogonal projection on the baseplate 100 of the encapsulation unit 511. For a structure of the display panel in the embodiment, as well as a further improvement, reference may be made to the relevant descriptions of the above-mentioned embodiments (such as the embodiment shown in FIG. 13), and the structure may not be repeated here.

In at least one embodiment of the present disclosure, the centroid of the orthogonal projection on the baseplate 100 of the first electrode 210, is located between the centroid of the orthogonal projection on the baseplate 100of the encapsulation unit 511 and the orthogonal projection on the baseplate 100 of the first electrode edge 210a. For a structure of the display panel in the embodiment, as well as a further improvement, reference may be made to the relevant descriptions of the above-mentioned embodiments (such as the embodiment shown in FIG. 13), and the structure may not be repeated here.

According to at least one embodiment of the present disclosure, a display apparatus is provided. The display apparatus includes the display panel described in any of the above-mentioned embodiments. For example, the display apparatus may be any product or component with a display function, such as a television, a digital camera, a mobile phone, a watch, a tablet computer, a notebook computer, or a navigation device.

It should be understood that the various processes above-mentioned may be reordered, with steps added or deleted. For example, the steps described in the present disclosure may be executed in parallel, sequentially, or in a different order, as long as the desired results of the embodiments of the present disclosure may be achieved, and no limitation is imposed herein.

The above-mentioned specific embodiments do not constitute a limitation on the protection scope of the present disclosure. Various modifications, combinations, sub-combinations, and substitutions may be made in accordance with design requirements and other factors. Any modifications, equivalent substitutions, or improvements made within the spirit and principles of the present disclosure shall fall within the protection scope of the present disclosure.

The above descriptions merely relate to exemplary embodiments of the present disclosure and are not intended to limit the present disclosure. Any modifications, equivalent substitutions, or other variations made within the spirit and principles of the present disclosure should be included within the protection scope of the present disclosure.

What is claimed is:

1. A display panel, comprising:
a baseplate;
a plurality of light-emitting devices;
an isolation structure, located on the baseplate and comprising a plurality of isolation openings; and
a pixel defining layer, located on the baseplate and comprising a plurality of pixel openings, the pixel opening communicated with the isolation opening;
wherein the light-emitting device comprises a first electrode, a light-emitting functional layer, and a second electrode sequentially stacked on the baseplate, the light-emitting functional layer and the second electrode of the light-emitting device are confined in the isolation opening and the pixel opening, and at the pixel opening and the isolation opening of at least one light-emitting device, orthogonal projections on the baseplate of at least two positions on an edge of the pixel opening are at differing distances from an orthogonal projection on the baseplate of an edge of the isolation opening.

2. The display panel according to claim 1, wherein at the pixel opening and the isolation opening of the at least one light-emitting device, the orthogonal projection on the baseplate of the edge of the isolation opening comprises a plurality of isolation opening projection edges, and
a distance, between a centroid of an orthogonal projection on the baseplate of the pixel opening and a part of the plurality of isolation opening projection edges, is less than a distance between the centroid of the orthogonal projection on the baseplate of the pixel opening and other part of the plurality of isolation opening projection edges.

3. The display panel according to claim 1, wherein an orthogonal projection on the baseplate of the pixel opening comprises a first pixel opening projection edge and a second pixel opening projection edge opposite to each other, and
a distance, between the first pixel opening projection edge and the orthogonal projection on the baseplate of the edge of the isolation opening, is less than a distance between the second pixel opening projection edge and the orthogonal projection on the baseplate of the edge of the isolation opening.

4. The display panel according to claim 1, wherein an orthogonal projection on the baseplate of the pixel opening comprises a third pixel opening projection edge and a fourth pixel opening projection edge, a length of the third pixel opening projection edge is greater than a length of the fourth pixel opening projection edge, and
a distance, between the third pixel opening projection edge and the orthogonal projection on the baseplate of the edge of the isolation opening, is less than a distance between the fourth pixel opening projection edge and the orthogonal projection on the baseplate of the edge of the isolation opening.

5. The display panel according to claim 3, wherein the first pixel opening projection edge corresponds to a first side of the isolation opening, the second pixel opening projection edge corresponds to a second side of the isolation opening, and
the second electrode overlaps with the isolation structure, a distance between the baseplate and an end, facing away from the baseplate, of a part of the second electrode overlapping with the isolation structure on the first side, is greater than a distance between the baseplate and an end, facing away from the baseplate, of a part of the second electrode overlapping with the isolation structure on the second side; and/or the second electrode overlaps with the isolation structure, a thickness, of the part of the second electrode overlapping with the isolation structure on the first side, is greater than a thickness of the part of the second electrode overlapping with the isolation structure on the second side.

6. The display panel according to claim 1, wherein
a shape of an orthogonal projection on the baseplate of the pixel opening corresponding to the at least one light-emitting device is a hexagon, and the hexagon comprises two opposite first straight edges, two opposite first oblique edges, and two opposite second oblique edges, the first straight edge is located between the first oblique edge and the second oblique edge, a distance, between an orthogonal projection on the baseplate of one first straight edge and the orthogonal projection on the baseplate of the edge of the isolation opening, is less than a distance between an orthogonal projection on the baseplate of the other first straight edge and the orthogonal projection on the baseplate of the edge of the isolation opening,
the plurality of light-emitting devices comprise a first-type light-emitting device, a second-type light-emitting device and a third-type light-emitting device with different emitting colors, the pixel openings with orthogonal projections on the baseplate of hexagonal shape are the pixel openings corresponding to the first-type light-emitting device and the third-type light-emitting device; the pixel opening corresponding to the second-type light-emitting device comprises two opposite second straight edges, two opposite third oblique edges and two opposite arc edges, the second straight edge is located between the third oblique edge and the arc edge, and in the pixel opening corresponding to the second-type light-emitting device, a distance, between an orthogonal projection of one second straight edge on the baseplate and the orthogonal projection on the baseplate of the edge of the isolation opening, is less than a distance between an orthogonal projection on the baseplate of the other second straight edge and the orthogonal projection on the baseplate of the edge of the isolation opening; and
the first straight edge and the second straight edge are parallel.

7. The display panel according to claim 3, wherein the first pixel opening projection edge corresponds to a first side of the isolation opening, the second pixel opening projection edge corresponds to a second side of the isolation opening, and
the second electrode overlaps the isolation structure on the first side, and a gap is provided between the second electrode and the isolation structure on the second side.

8. The display panel according to claim 7, wherein a distance, between an orthogonal projection on the baseplate of an edge of the pixel opening and the orthogonal projection on the baseplate of the edge of the isolation opening, ranges from 0.3 μm to 10 μm.

9. The display panel according to claim 3, wherein the first pixel opening projection edge corresponds to a first side of the isolation opening, an orthogonal projection of the first side of the isolation opening on the baseplate is a straight edge; and
the baseplate comprises a scan signal line, the orthogonal projection on the baseplate of the first side of the isolation opening is parallel or perpendicular to the scan signal line.

10. The display panel according to claim 3, wherein the plurality of light-emitting devices comprise light-emitting devices with different emitting colors, and at the pixel opening and isolation opening of the light-emitting device with every emitting color, orthogonal projections of at least two positions on the edge of the pixel opening on the baseplate are at differing distances from the orthogonal projection on the baseplate of the edge of the isolation opening; or
at the pixel opening and isolation opening of the light-emitting device with at least one emitting color, orthogonal projections of at least two positions on the edge of the pixel opening on the baseplate are at differing distances from the orthogonal projection on the baseplate of the edge of the isolation opening, and at the pixel opening and isolation opening of the light-emitting device with at least one other emitting color, orthogonal projections of at least two positions on the edge of the pixel opening on the baseplate are at same distances from the orthogonal projection of the edge of the isolation opening on the baseplate.

11. The display panel according to claim 3, wherein the plurality of light-emitting devices comprise light-emitting devices with different emitting colors, the pixel openings corresponding to the light-emitting devices of at least two emitting colors comprise a first pixel opening projection edge and a second pixel opening projection edge, for the light-emitting devices corresponding to the pixel openings comprising the first pixel opening projection edge and the second pixel opening projection edge,
in the pixel openings respectively corresponding to the light-emitting devices with different emitting colors, directions from the first pixel opening projection edge to the second pixel opening projection edge are the same; or in the pixel openings respectively corresponding to the light-emitting devices with different emitting colors, directions from the first pixel opening projection edge to the second pixel opening projection edge are different; and/or
in the pixel openings respectively corresponding to the light-emitting devices with different emitting colors, differences between a distance from the first pixel opening projection edge to a centroid of an orthogonal projection of the isolation opening on the baseplate, and a distance from the second pixel opening projection edge to the centroid of the orthogonal projection of the isolation opening on the baseplate are equal; or in the pixel openings respectively corresponding to the light-emitting device with different emitting colors, the differences between the distance from the first pixel opening projection edge to the centroid of the orthogonal projection on the baseplate of the isolation opening, and the distance from the second pixel opening projection edge to the centroid of the orthogonal projection on the baseplate of the isolation opening are different.

12. The display panel according to claim 1, wherein
a centroid of an orthogonal projection on the baseplate of at least one first electrode coincides with a centroid of an orthogonal projection on the baseplate of the isolation opening, and the centroid of the orthogonal projection on the baseplate of the at least one first electrode is located outside a centroid of an orthogonal projection on the baseplate of the pixel opening; or
the centroid of the orthogonal projection on the baseplate of the at least one first electrode is located outside the centroid of the orthogonal projection on the baseplate of the isolation opening, and the centroid of the orthogonal projection on the baseplate of the at least one first electrode coincides with the centroid of the orthogonal projection on the baseplate of the pixel opening; or
the centroid of the orthogonal projection on the baseplate of the at least one first electrode is located outside the centroid of the orthogonal projection on the baseplate of the isolation opening, and the centroid of the orthogonal projection on the baseplate of the at least one first electrode is located outside the centroid of the orthogonal projection on the baseplate of the pixel opening, and the centroid of the orthogonal projection on the baseplate of the isolation opening is located outside the centroid of the orthogonal projection on the baseplate of the pixel opening.

13. The display panel according to claim 3, wherein
a centroid of at least one second electrode coincides with a centroid of the isolation opening; or
the first pixel opening projection edge corresponds to a first side of the isolation opening, the second pixel opening projection edge corresponds to a second side of the isolation opening, the second electrode overlaps the isolation structure on the first side, and a gap is provided between the second electrode and the isolation structure on the second side, wherein a centroid, of an orthogonal projection on the baseplate of the second electrode on the baseplate, is located between a centroid of an orthogonal projection on the baseplate of the isolation opening and the first pixel opening projection edge, and a centroid, of the orthogonal projection on the baseplate of the pixel opening, is located between the centroid of the orthogonal projection on the baseplate of the second electrode and the first pixel opening projection edge.

14. The display panel according to claim 1, wherein at at least one isolation opening, a centroid, of an orthogonal projection on the baseplate of a gap between adjacent first electrodes, is located outside a centroid of an orthogonal projection on the baseplate of the isolation opening.

15. The display panel according to claim 14, wherein a centroid of an orthogonal projection on the baseplate of a part of the isolation structure located between a gap of two adjacent isolation openings, is located outside a centroid of an orthogonal projection on the baseplate of a gap between the first electrodes corresponding to the two adjacent isolation openings.

16. The display panel according to claim 15, wherein at the isolation opening with a centroid offset from the first electrode, the first electrode comprises a first electrode edge and a second electrode edge opposite to each other, and
an orthogonal projection on the baseplate of the first electrode edge is located within an orthogonal projection on the baseplate of the isolation structure, an orthogonal projection on the baseplate of the second electrode edge is located outside the orthogonal projection on the baseplate of the isolation structure, and the orthogonal projection on the baseplate of the second electrode edge is located within the orthogonal projection on the baseplate of the isolation opening.

17. The display panel according to claim 16, wherein the first electrode comprises a main body portion and a connecting portion connected with the main body portion, the main body portion comprises the first electrode edge and the second electrode edge, an orthogonal projection on the baseplate of the connecting portion is located within the orthogonal projection on the baseplate of the isolation structure; and
the baseplate comprises a pixel circuit layer and a planarization layer, the planarization layer located between the pixel circuit layer and the first electrode, the planarization layer is provided with a via, the connecting portion is located in the via, so as to make the main body portion be electrically connected to the pixel circuit layer through the via and the connecting portion.

18. The display panel according to claim 16, wherein a distance between the baseplate and a surface, facing away from the baseplate, of a part of the isolation structure on a side on which the first electrode edge is located, is greater than a distance between the baseplate and a surface, facing away from the baseplate, of a part of the isolation structure on a side on which the second electrode edge is located,
for a part of the isolation structure located between two adjacent isolation openings, a distance between the baseplate and a surface, facing away from the baseplate, of a part, adjacent to one of the adjacent isolation openings, of the isolation structure, is greater than a distance between the baseplate and a surface, facing away from the baseplate, of a part, adjacent to the other isolation opening, of the isolation structure, and
an orthogonal projection on the baseplate of the part of the isolation structure on the side on which the first electrode edge is located, is located within an orthogonal projection on the baseplate of the first electrode, and an orthogonal projection on the baseplate of the part of the isolation structure on the side on which the second electrode edge is located, is located outside the orthogonal projection on the baseplate of the first electrode.

19. The display panel according to claim 16, wherein the light-emitting functional layer and the second electrode of the light-emitting device are confined in the isolation opening and the pixel opening, an edge part of the first electrode is located between the pixel defining layer and the baseplate, and
on a side on which the second electrode edge is located, a part of the pixel defining layer covering the first electrode constitutes a stepped structure, and an orthogonal projection on the baseplate of the stepped structure, is located within the orthogonal projection on the baseplate of the isolation opening.

20. The display panel according to claim 16, wherein
a distance, between the baseplate and an edge of the light-emitting functional layer on a side on which the first electrode edge is located, is greater than a distance between the baseplate and an edge of the light-emitting functional layer on a side on which the second electrode edge is located; and/or
the display panel further comprises a first encapsulation layer covering the isolation opening, the first encapsulation layer comprises encapsulation units covering the light-emitting devices respectively, and a distance, between the baseplate and an edge of the encapsulation unit on the side on which the first electrode edge is located, is greater than a distance between the baseplate and an edge of the encapsulation unit on the side on which the second electrode edge is located.

21. The display panel according to claim 16, wherein the second electrode overlaps one of two opposite side walls of the isolation structure, and a gap is provided between the second electrode and the other side wall,
the second electrode overlaps the isolation structure on a side on which the first electrode edge is located, and a gap is provided between the second electrode and the isolation structure on a side on which the second electrode edge is located;
the plurality of light-emitting devices comprise light-emitting devices with different emitting colors, and for each of the light-emitting device with the same emitting color, a position in which the second electrode overlaps a side wall of the isolation structure is on the same side of the isolation opening.

22. The display panel according to claim 1, wherein the display panel further comprises a touch function layer, the touch function layer is located on a side, facing away from the baseplate, of the isolation structure, the touch function layer constitutes a first mesh pattern, the pixel defining layer constitutes a second mesh pattern, the pixel opening is a mesh hole of the second mesh pattern,
the first mesh pattern and the second mesh pattern both comprise a plurality of mesh lines, an orthogonal projection on the baseplate of a centerline of at least one mesh line of the first mesh pattern, coincides with an orthogonal projection on the baseplate of a centerline of at least one mesh line of the second mesh pattern; and
gaps between the first electrodes constitute a third mesh pattern, the third mesh pattern comprises a plurality of mesh lines, and the orthogonal projection on the baseplate of the centerline of the at least one mesh line of the first mesh pattern, is located outside an orthogonal projection on the baseplate of a centerline of at least one mesh line of the third mesh pattern.

23. The display panel according to claim 1, wherein the display panel further comprises a touch function layer, and the touch function layer is located on a side, facing away from the baseplate, of the isolation structure, the touch function layer constitutes a first mesh pattern, gaps between the first electrodes constitute a third mesh pattern,
the first mesh pattern and the third mesh pattern both comprise a plurality of mesh lines, an orthogonal projection on the baseplate of the first mesh pattern, is located within an orthogonal projection on the baseplate of the isolation structure, and an orthogonal projection on the baseplate of a centerline of at least a part of the mesh lines of the first mesh pattern, is located outside an orthogonal projection on the baseplate of a centerline of the mesh line of the third mesh pattern, and
the first mesh pattern comprises mesh lines comprising a first-type mesh line extending along a first direction and a second-type mesh line extending along a second direction, the third mesh pattern comprises mesh lines comprising a third-type mesh line extending along the first direction and a fourth type mesh line extending along the second direction, the first direction intersects with the second direction, wherein an orthogonal projection on the baseplate of a centerline of the first-type mesh line coincides with an orthogonal projection on the baseplate of a centerline of the third-type mesh line, and an orthogonal projection on the baseplate of a centerline of the second-type mesh line is located outside an orthogonal projection on the baseplate of a centerline of the fourth type mesh line.

24. The display panel according to claim 1, wherein the plurality of light-emitting devices comprise first-type light-emitting devices, second-type light-emitting devices and third-type light-emitting devices with different emitting colors, the first-type light-emitting devices, the second-type light-emitting devices and the third-type light-emitting devices are arranged in a plurality of pixel units, each pixel unit comprises one first-type light-emitting device, two second-type light-emitting devices and two third-type light-emitting devices,
in each pixel unit, centroids of orthogonal projections on the baseplate of the isolation openings corresponding to the two second-type light-emitting devices are located at first vertices of a third virtual quadrilateral, centroids of orthogonal projections on the baseplate of the isolation openings corresponding to the two third-type light-emitting devices are located at second vertices of the third virtual quadrilateral, the first vertices and second vertices alternate and are spaced apart, an orthogonal projection on the baseplate of the isolation opening corresponding to the first-type light-emitting device is located in the third virtual quadrilateral,
centroids of orthogonal projections of the pixel openings corresponding to the two second-type light-emitting devices and two third-type light-emitting devices of the pixel unit on the baseplate are vertices of a fourth virtual quadrilateral, the third virtual quadrilateral and the fourth virtual quadrilateral are incompletely coincident, a centroid of the third virtual quadrilateral is located outside a centroid of the fourth virtual quadrilateral, and
in the third virtual quadrilateral, first distances between a centroid of the isolation opening corresponding to the first-type light-emitting device and a centroid of the isolation opening corresponding to any third-type light-emitting device are equal, second distances between a centroid of the isolation opening corresponding to the first-type light-emitting device and a centroid of the isolation opening corresponding to any second-type light-emitting device are equal, and the first distance equals the second distance.

25. A display panel, comprising:
a baseplate;
a plurality of light-emitting devices;
an isolation structure, located on the baseplate and comprising a plurality of isolation openings; and
a pixel defining layer, located on the baseplate and comprising a plurality of pixel openings, the pixel opening communicated with the isolation opening;
wherein the light-emitting device comprises a first electrode, a light-emitting functional layer, and a second electrode sequentially stacked on the baseplate, the light-emitting functional layer and the second electrode of the light-emitting device are confined in the isolation opening and the pixel opening, and for the pixel opening and the isolation opening of the same light-emitting device, a centroid of an orthogonal projection on the baseplate of the pixel opening is located outside a centroid of an orthogonal projection on the baseplate of the isolation opening.

26. The display panel according to claim 25, wherein the orthogonal projection on the baseplate of the pixel opening comprises a third pixel opening projection edge and a fourth pixel opening projection edge, a length of the third pixel opening projection edge is greater than a length of the fourth pixel opening projection edge, and
a distance, between the third pixel opening projection edge and an orthogonal projection on the baseplate of an edge of the isolation opening, is less than a distance between the fourth pixel opening projection edge and the orthogonal projection on the baseplate of the edge of the isolation opening.

27. The display panel according to claim 25, wherein a first pixel opening projection edge corresponds to a first side of the isolation opening, a second pixel opening projection edge corresponds to a second side of the isolation opening; and
the second electrode overlaps with the isolation structure, a distance, between the baseplate and an end, facing away from the baseplate, of a part of the second electrode overlaps with the isolation structure on the first side, is greater than a distance between the baseplate and an end, facing away from the baseplate, of a part of the second electrode overlaps with the isolation structure on the second side; and/or
the second electrode overlaps with the isolation structure, a thickness of the part of the second electrode overlapping with the isolation structure on the first side, is greater than a thickness of the part of the second electrode overlapping with the isolation structure on the second side.

28. A display panel, comprising:
a baseplate;
a plurality of light-emitting devices; and
an isolation structure, located on the baseplate and comprising a plurality of isolation openings;
wherein the light-emitting device comprises a first electrode, a light-emitting functional layer, and a second electrode sequentially stacked on the baseplate, the light-emitting functional layer and the second electrode of the light-emitting device are confined in the isolation opening, and at at least one isolation opening, a centroid of an orthogonal projection on the baseplate of the first electrode, is located outside a centroid of an orthogonal projection on the baseplate of the isolation opening.

29. The display panel according to claim 28, wherein the display panel further comprises a pixel defining layer located between the baseplate and the isolation structure, wherein the pixel defining layer comprises a pixel opening communicated with the isolation opening, the light-emitting functional layer and the second electrode of the light-emitting device are confined in the isolation opening and the pixel opening, and
the centroid of the orthogonal projection on the baseplate of the first electrode, is located outside a centroid of an orthogonal projection on the baseplate of the pixel opening.

30. The display panel according to claim 28, wherein at the isolation opening with a centroid offset from the first electrode, the first electrode comprises a first electrode edge and a second electrode edge opposite to each other, and
an orthogonal projection on the baseplate of the first electrode edge is located within an orthogonal projection on the baseplate of the isolation structure, an orthogonal projection on the baseplate of the second electrode edge is located outside an orthogonal projection on the baseplate of the isolation structure, and the orthogonal projection on the baseplate of the second electrode edge is located within an orthogonal projection on the baseplate of the isolation opening,
